(19) United States
(12) Patent Application Publication
(10) Pub. No.: US 2026/0171162 A1
(43) Pub. Date: Jun. 18, 2026

(54) RECYCLE CURRENT DURING SENSE OF MEMORY CELLS

(71) Applicant: Sandisk Technologies, Inc., Milpitas, CA (US)

(72) Inventors: Kazuma Mori, Kanagawa (JP); Naoki Ookuma, Kita-ku (JP); Hiroki Yabe, Yokohama (JP)

(73) Assignee: Sandisk Technologies, Inc., Milpitas, CA (US)

(21) Appl. No.: 18/982,906

(22) Filed: Dec. 16, 2024

(51) Int. Cl. G11C 16/26; G11C 16/04; G11C 16/34

(52) U.S. Cl. CPC G11C 16/26; G11C 16/0483; G11C 16/3459

(57) ABSTRACT

Technology for a non-volatile storage system and method of operating a non-volatile storage system that recycles current (e.g., Icc) to reduce the amount of current used during sense operations. The memory system applies voltages to memory cells that result in first currents flowing through a first set of NAND strings and second currents flowing through a second set of NAND strings. During the sense operation a first set of sense amplifiers sense selected memory cells on the first set of NAND strings and a second set of sense amplifiers sense selected memory cells on the second set of NAND strings. The memory system operates the first set of sense amplifiers and the set plurality of sense amplifiers to recycle the first currents for use as a current source for the second currents during the sense operation.

### BACKGROUND

The present disclosure relates to non-volatile memory.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. Non-volatile memory allows information to be stored and retained even when the non-volatile memory is not connected to a source of power (e.g., a battery).

A memory structure in the memory system typically contains many memory cells and various control lines. The memory structure may be grouped into units commonly referred to as blocks. For example, a block in a NAND memory system contains many NAND strings. A NAND string contains memory cell transistors connected in series, a drain side select gate at one end, and a source side select gate at the other end. Each NAND string is associated with a bit line. The bit line is typically connected to a sense amplifier in order to sense a selected memory cell on the NAND string. The drain side select gate is used to connect/disconnect the channel of the NAND string to/from the bit line. The source side select gate is used to connect/disconnect the channel of the NAND string to/from a source line that is common to many NAND strings in the block. The block typically has many word lines that provide voltages to the control gates of the memory cell transistors. Typically, a word line connects to the control gates of memory cells on many NAND strings in the block.

A selected memory cell on a NAND may be read by applying a read reference voltage to the control gate of the selected memory cell while applying a read pass voltage to the control gates of other memory cells (“unselected memory cells”) on the NAND string. The read reference voltage will test whether the Vt of the memory cell is above/below the read reference voltage. The read pass voltage has a sufficiently high magnitude to be above the highest Vt of any of the unselected memory cells. Thus, the unselected memory cells should each turn on. The selected memory cell might or might not turn on and conduct a significant current, depending on its Vt. The bit line current may be sensed to determine the state of the selected memory cell. The amount of current drawn by the storage system during the read process will vary over time throughout the read. There could be large peaks in the current drawn by the storage system during certain parts of the read.

The memory system may have a number of semiconductor dies that contain memory cells. Each of these semiconductor dies may be organized as a number of planes, with each plane having circuitry such as sense amplifiers that are capable of carrying out operations such as read. Therefore, read operations can be performed in parallel in each plane on a semiconductor die. Such parallel read operations can consume a substantial amount of current.

The semiconductor dies in the storage system will typically draw current/power from a host system. There are often limits to the peak current that can be provided from a host system to the storage system. The term “Icc” is typically used to refer to a current provided to the storage system by a power source. The term “peak Icc” is used to refer to the peak amount of current that is drawn by the storage system. The term “specified peak Icc” refers to a maximum allowed peak Icc. For example, there may be a specification that defines the specified peak Icc. If the peak current drawn by the storage system is greater than the specified peak Icc, then the magnitude of the supply voltage may drop, which can result in operation failure in the storage system. Much of the power and/or current that is used by the storage system is used to perform memory operations such as reading the memory cells on memory dies. Hence, reducing the power and/or current used by the semiconductor dies is important in order to keep the peak Icc of the storage system within the specified peak Icc. Reducing the current used by the semiconductor dies is also beneficial in reducing the average Icc.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of an integrated memory assembly.

FIGS. 2C and 2D depict different embodiments of integrated memory assemblies.

FIG. 3 depicts circuitry used to sense data from non-volatile memory.

FIG. 4 is a perspective view of a portion of one example embodiment of a monolithic three dimensional memory structure.

FIG. 4A is a block diagram of one embodiment of a memory structure having two planes.

FIG. 4B is a block diagram depicting a top view of a portion of block of memory cells.

FIG. 4C depicts a portion of one embodiment of a three dimensional memory structure showing a cross-sectional view along line AA of FIG. 4B.

FIG. 4D depicts a view of the region 445 of FIG. 4C.

FIG. 4E is a schematic diagram of a portion of one embodiment of a block, depicting several NAND strings.

FIG. 4F1, 4F2, 4F3, and 4F4 are schematic diagrams of a portion one embodiment of a block, depicting several NAND strings.

FIGS. 5A and 5B depicts threshold voltage distributions.

FIGS. 6A, 6B, 6C, and 6D are diagrams illustrating a portion of embodiments of a memory system that recycle current during a sense operation of non-volatile memory.

FIG. 7 is a schematic diagram of one example of a sense amplifier that may be used when sensing a memory cell having a current that flows from bit line to source line.

FIG. 8 depicts timing signals in sense amplifier of FIG. 7 in connection with an embodiment of sensing a memory cell.

FIG. 9 is a schematic diagram of one example of a sense amplifier that may be used when sensing a memory cell having a current that flows from source line to bit line.

FIG. 10 depicts timing signals in sense amplifier of FIG. 9 in connection with an embodiment of sensing a memory cell.

FIG. 11 is a schematic diagram of two sense amplifiers in an embodiment that allows recycling of current during sensing a memory cell.

FIG. 12 shows voltages versus time at the SEN nodes and SCOM nodes of the sense amplifiers in FIG. 11.

FIG. 13 is a schematic diagram of two sense amplifiers in an embodiment that allows recycling of current during sensing a memory cell.

FIG. 14 shows voltages versus time at the SEN nodes and SCOM nodes of the sense amplifiers in FIG. 13.

FIG. 15 is a schematic diagram of two sense amplifiers in an embodiment that allows recycling of current during sensing a memory cell.

FIG. 16 shows voltages versus time at the SEN nodes and SCOM nodes of the sense amplifiers in FIG. 15.

FIG. 17 is a schematic diagram of two sense amplifiers in a configuration that allows recycling of current during sensing a memory cell.

FIG. 18 shows voltages versus time at the SEN nodes and SCOM nodes of the sense amplifiers in FIG. 17.

FIGS. 19A and 19B each show an example NAND string in which memory cells connected to the same word line are selected for read.

FIG. 20 shows an example set of Vt distributions for sensing with the current flowing source line to bit line and an example set of Vt distributions for sensing with the current flowing bit line to source line.

FIGS. 21A and 21B shows schematics of example NAND strings illustrating selecting a different word line for a NAND string having Icell flowing from bit line to source line than a NAND string having Icell flowing from source line to bit line.

FIG. 22 shows an example set of Vt distributions for sensing with the current flowing source line to bit line and an example set of Vt distributions for sensing with the current flowing bit line to source line for the technique used in FIGS. 21A and 21B.

### DETAILED DESCRIPTION

Technology is disclosed herein for a non-volatile storage system and method of operating a non-volatile storage system that recycles current (e.g., Icc) to reduce the amount of current used during sense operations. The memory system applies voltages to memory cells that result in first currents flowing through a first set of NAND strings and second currents flowing through a second set of NAND strings. During the sense operation (e.g., read, verify) a first set of sense amplifiers sense selected memory cells on the first set of NAND strings and a second set of sense amplifiers sense selected memory cells on the second set of NAND strings. The memory system operates the first set of sense amplifiers and the second set of sense amplifiers to recycle the first currents for use as a source of current for the second currents during the sense operation thereby reducing Icc consumption.

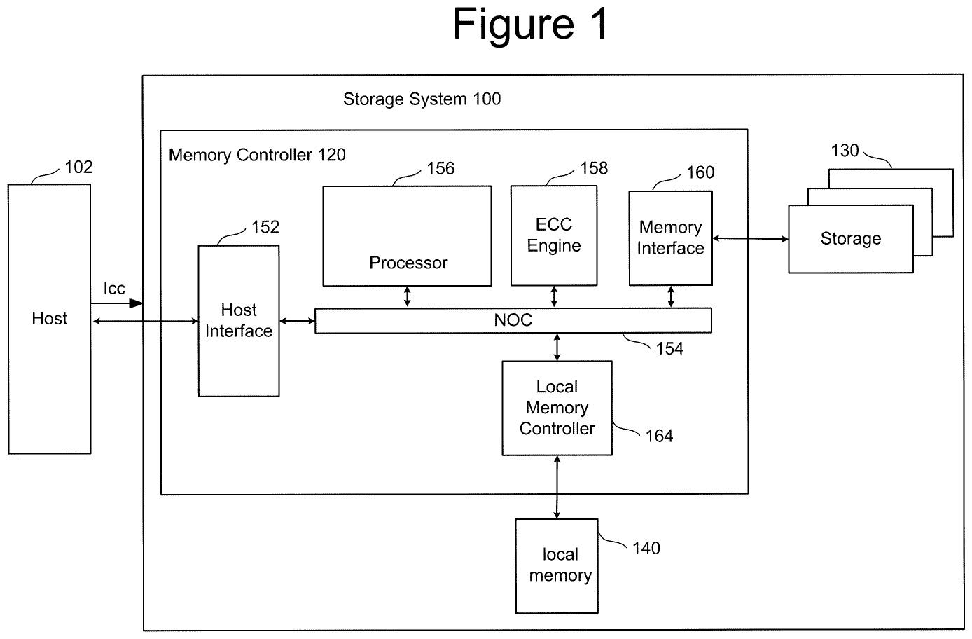

FIG. 1 is a block diagram of one embodiment of a storage system 100 that implements the technology described herein. In one embodiment, storage system 100 is a solid state drive (“SSD”). Storage system 100 can also be a memory card, USB drive or other type of storage system. The proposed technology is not limited to any one type of storage system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 (or storage controller) connected to non-volatile storage 130 and local high speed memory 140 (e.g., DRAM, SRAM, MRAM). Local memory 140 is non-transitory memory, which may include volatile memory or non-volatile memory. Local high speed memory 140 is used by memory controller 120 to perform certain operations. For example, local high speed memory 140 may store logical to physical address translation tables (“L2P tables”).

Memory controller 120 comprises a host interface 152 that is connected to and in communication with host 102. In one embodiment, host interface 152 implements an NVM Express (NVMe) over PCI Express (PCIe). Other interfaces can also be used, such as SCSI, SATA, etc. In order to power its operations, the storage system 100 draws current (Icc) from the host 102. The current may be provided over a physical interface associated with the host interface 152.

Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, and local memory controller 164. Local memory controller 164 is used to operate and communicate with local high speed memory 140 (e.g., DRAM, SRAM, MRAM).

ECC engine 158 performs error correction services. For example, ECC engine 158 performs data encoding and decoding. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory die. One example implementation is to maintain tables (i.e., the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in a storage 130 and a subset of the L2P tables are cached (L2P cache) in the local high speed memory 140.

Memory interface 160 communicates with non-volatile storage 130. In one embodiment, memory interface provides a Toggle Mode interface. Other interfaces can also be used. In some example implementations, memory interface 160 (or another portion of controller 120) implements a scheduler and buffer for transmitting data to and receiving data from one or more memory die.

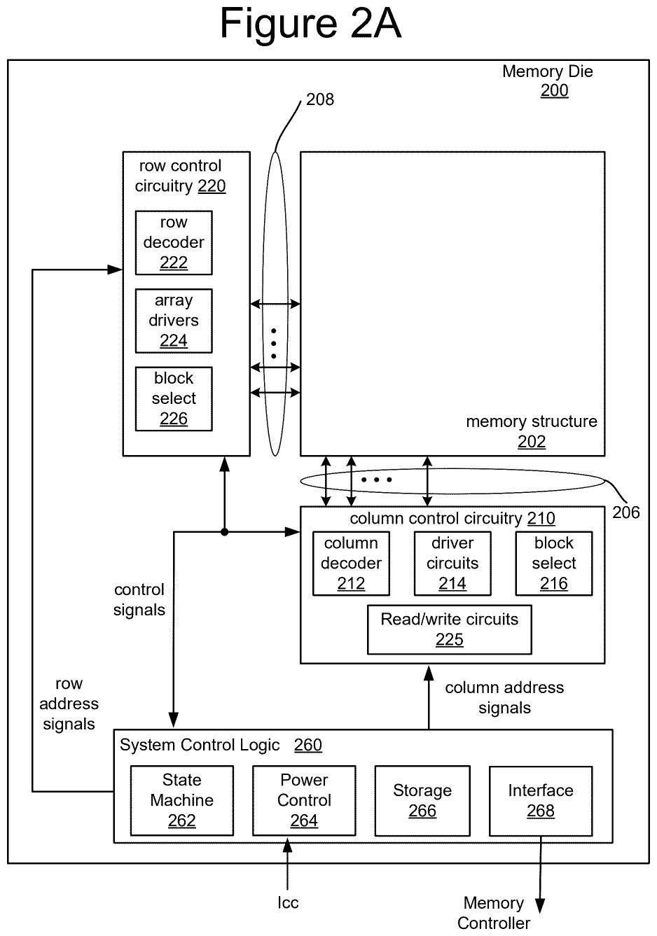

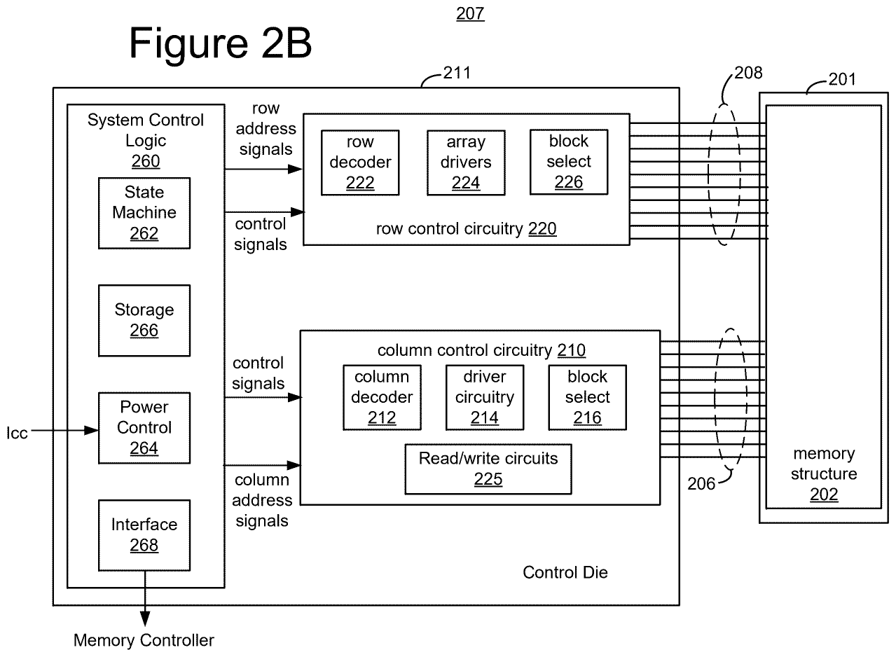

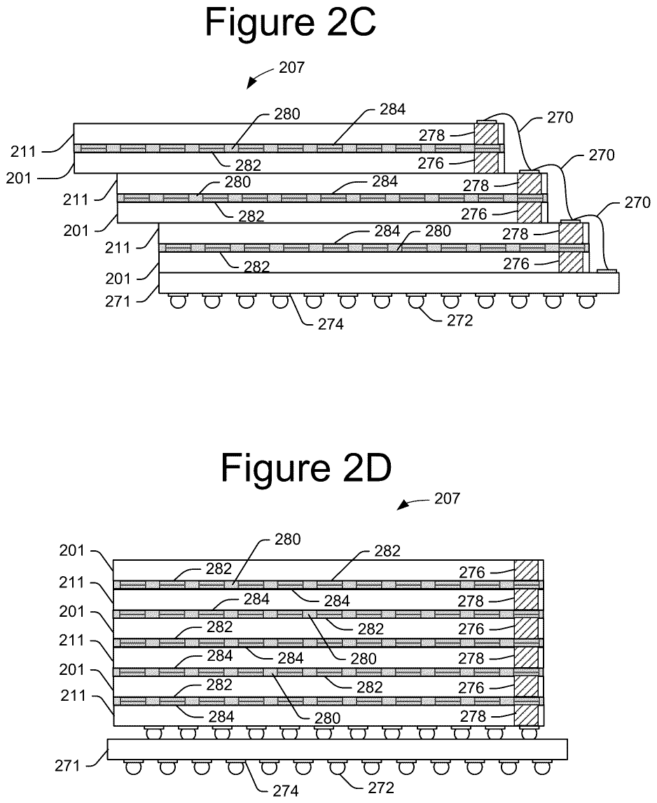

In one embodiment, non-volatile storage 130 comprises one or more memory dies. FIG. 2A is a functional block diagram of one embodiment of a memory die 200 that comprises non-volatile storage 130. Each of the one or more memory dies of non-volatile storage 130 can be implemented as memory die 200 of FIG. 2A. The components depicted in FIG. 2A are electrical circuits. Memory die 200 includes a memory structure 202 (e.g., memory array) that can comprise non-volatile memory cells (also referred to as non-volatile storage cells), as described in more detail below. The array terminal lines of memory structure 202 include the various layer(s) of word lines organized as rows, and the various layer(s) of bit lines organized as columns. However, other orientations can also be implemented. Memory die 200 includes row control circuitry 220, whose outputs are connected to respective word lines of the memory structure 202. Row control circuitry 220 receives a group of M row address signals and one or more various control signals from System Control Logic circuit 260, and typically may include such circuits as row decoders 222, array drivers 224, and block select circuitry 226 for both reading and writing (programming) operations. Row control circuitry 220 may also include read/write circuitry. Memory die 200 also includes column control circuitry 210 including read/write circuits 225. The read/write circuits 225 may contain sense amplifiers and data latches. The sense amplifier(s) input/outputs are connected to respective bit lines of the memory structure 202. Although only single block is shown for structure 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuitry 216, as well as read/write circuitry, and I/O multiplexers.

System control logic 260 receives data and commands from memory controller 120 and provides output data and status to the host. In some embodiments, the system control logic 260 (which comprises one or more electrical circuits) includes state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations and may include charge pumps and regulator circuit for creating regulating voltages. Thus, power control module 264 may include a voltage driver. The voltage driver may provide an operating voltage to one or more control lines in the memory structure 202. System control logic 260 includes storage 266 (e.g., RAM, registers, latches, etc.), which may be used to store parameters for operating the memory structure 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used. To power its operations, the memory die 200 receives power over the physical interface to the memory controller 120. The supply current (Icc) is depicted as being provided to the power control 264. The supply current (Icc) is typically provided over a line (e.g., pin, pad, etc.) that may be referred to as Vcc or the like in the physical interface (e.g., ONFI physical interface) to the memory controller 120.

In some embodiments, all the elements of memory die 200, including the system control logic 260, can be formed as part of a single die. In other embodiments, some or all of the system control logic 260 can be formed on a different die than the die that contains the memory structure 202.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe-Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

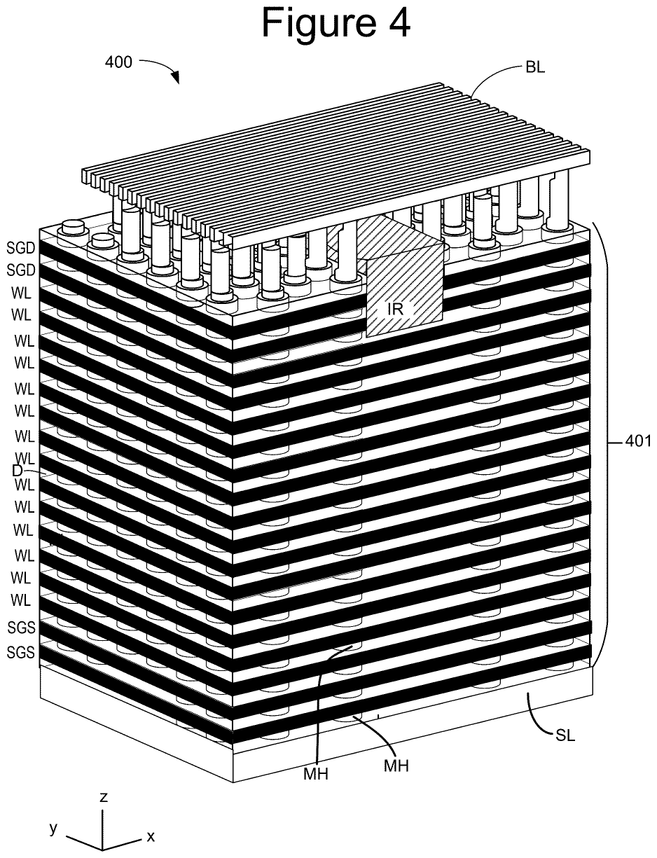

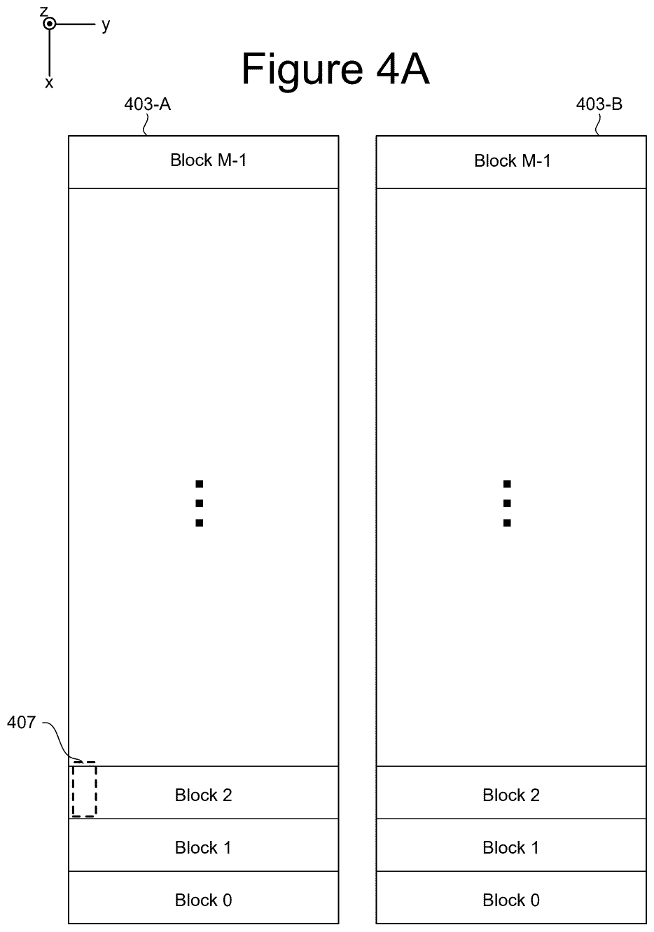

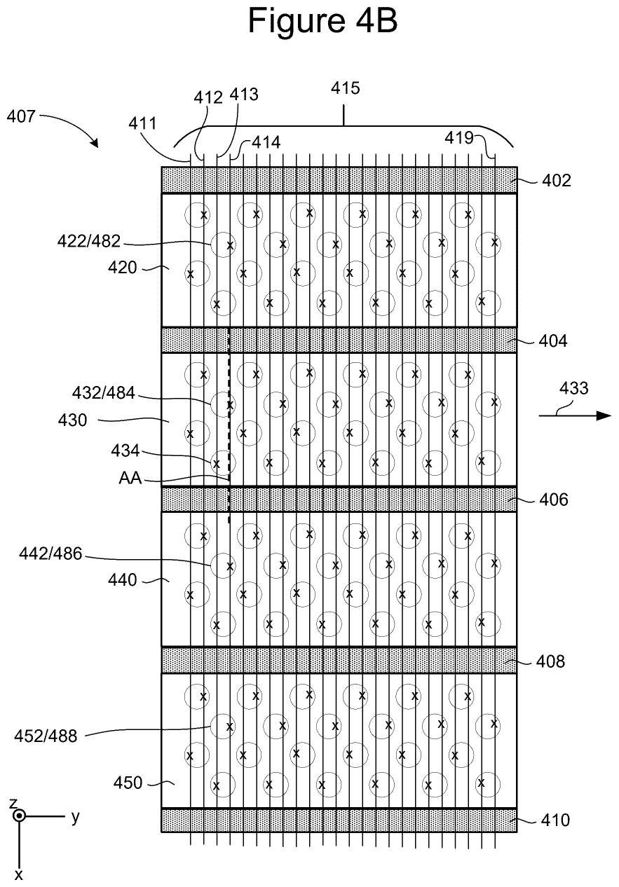

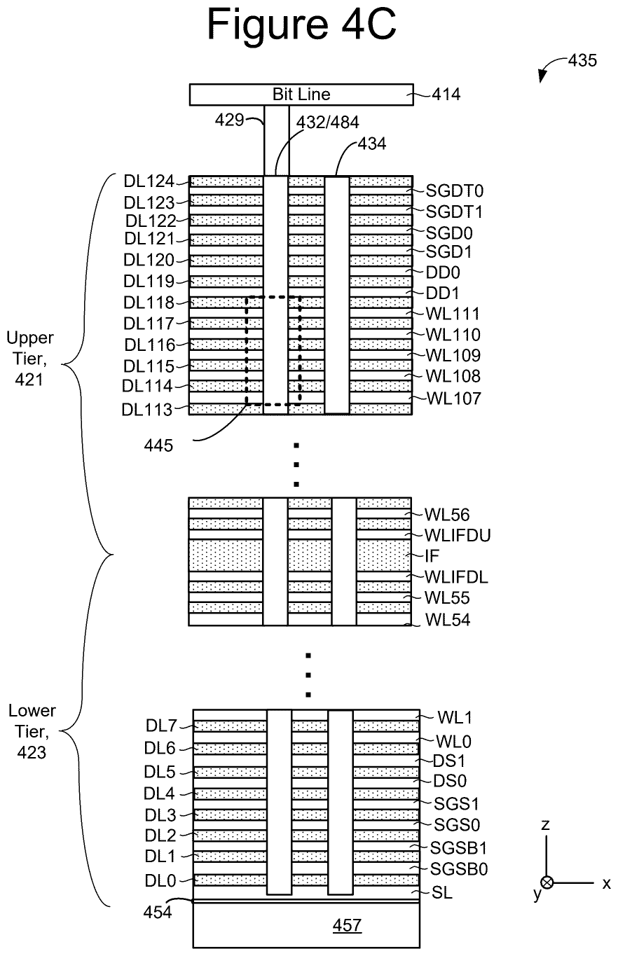

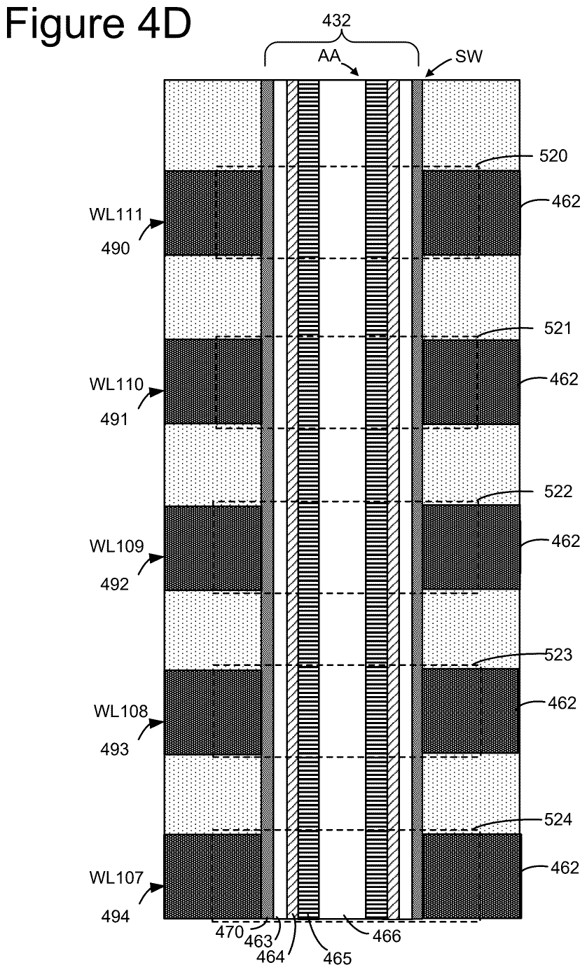

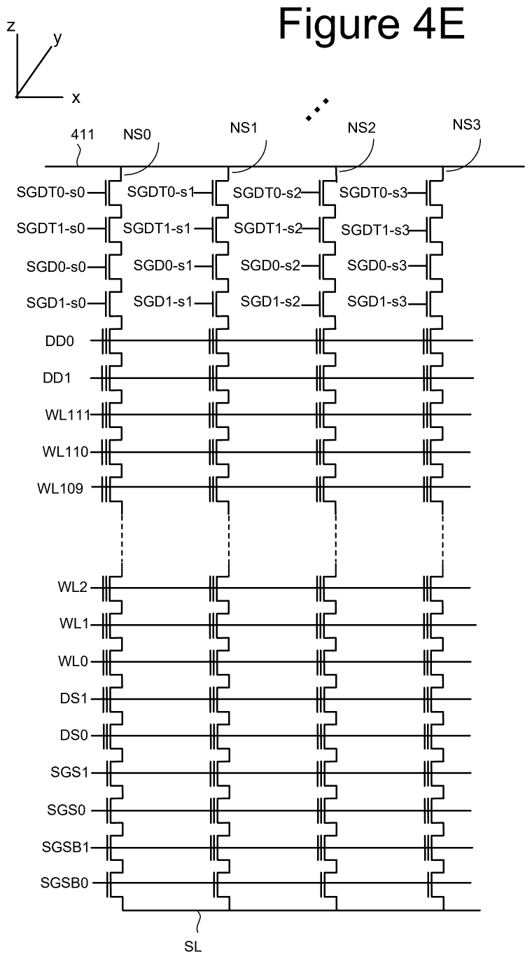

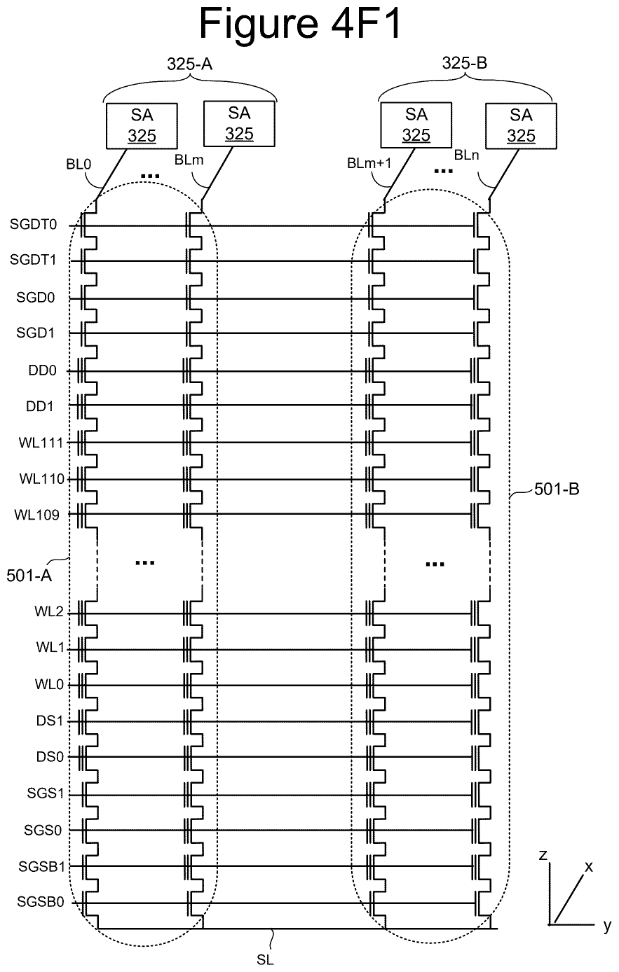

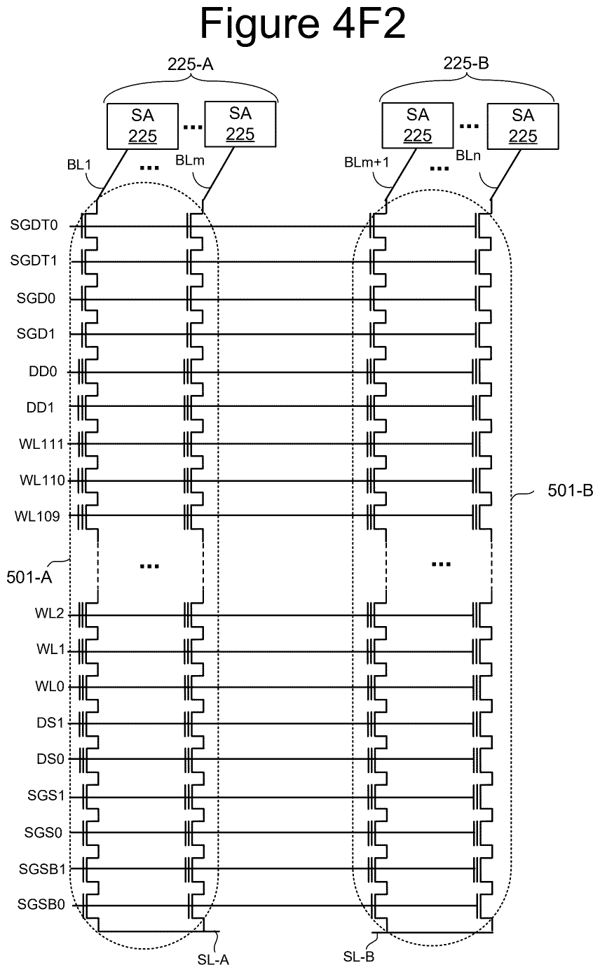

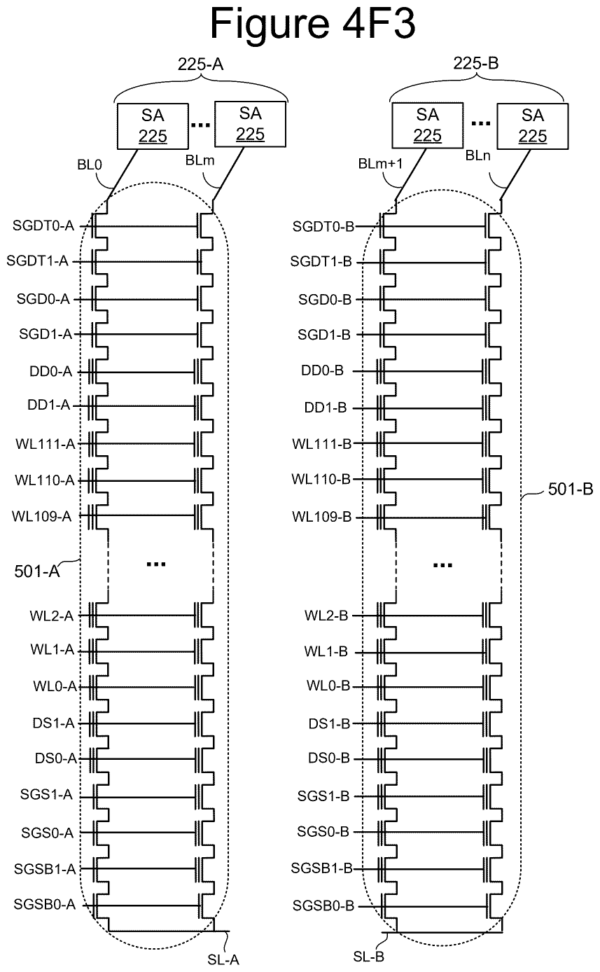

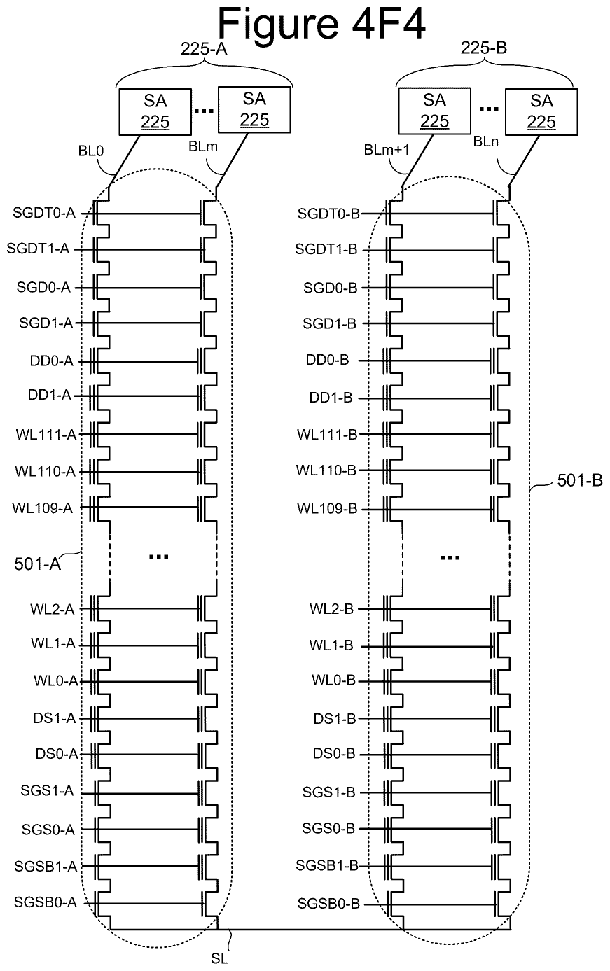

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies. Three-dimensional NAND structures (see, for example, FIG. 4) in particular may benefit from specialized processing operations.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the non-volatile storage 130 of storage system 100. The integrated memory assembly 207 includes two types of semiconductor dies (or more succinctly, “die”). Memory structure die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory structure die 201. In some embodiments, the memory structure die 201 and the control die 211 are bonded together.

FIG. 2B shows an example of the peripheral circuitry, including control circuits, formed in a peripheral circuit or control die 211 coupled to memory structure 202 formed in memory structure die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory structure die 201. In some embodiments, some of the circuitry in the system control logic 260 is located on the on the memory structure die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate controller 120 may also be used to fabricate system control logic 260, row control circuitry 220, and column control circuitry 210). Thus, while moving such circuits from a die such as memory structure die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including read/write circuits 225 on the control die 211 coupled to memory structure 202 on the memory structure die 201 through electrical paths 206. For example, electrical paths 206 may provide electrical connection between column decoder 212, driver circuitry 214, and block select 216 and bit lines of memory structure 202. Electrical paths may extend from column control circuitry 210 in control die 211 through pads on control die 211 that are bonded to corresponding pads of the memory structure die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select 226 are coupled to memory structure 202 through electrical paths 208. Each of electrical path 208 may correspond to a word line, dummy word line, or select gate line. Additional electrical paths may also be provided between control die 211 and memory structure die 201.

For purposes of this document, the phrases “a control circuit” or “one or more control circuits” can include any one of or any combination of memory controller 120, state machine 262, power control 264, all or a portion of system control logic 260, all or a portion of row control circuitry 220, all or a portion of column control circuitry 210, read/write circuits 225, sense amplifiers, a microcontroller, a microprocessor, and/or other similar functioned circuits. A control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit.

For purposes of this document, the term “apparatus” can include, but is not limited to, one or more of, storage system 100, memory controller 120, storage 130, memory die 200, integrated memory assembly 207, and/or control die 211.

In some embodiments, there is more than one control die 211 and more than one memory structure die 201 in an integrated memory assembly 207. In some embodiments, the integrated memory assembly 207 includes a stack of multiple control die 211 and multiple memory structure die 201. FIG. 2C depicts a side view of an embodiment of an integrated memory assembly 207 stacked on a substrate 271 (e.g., a stack comprising control die 211 and memory structure die). The integrated memory assembly 207 has three control dies 211 and three memory structure dies 201. In some embodiments, there are more than three memory structure dies 201 and more than three control dies 211. In FIG. 2C there are an equal number of memory structure dies 201 and control dies 211; however, in one embodiment, there are more memory structure dies 201 than control dies 211. For example, one control die 211 could control multiple memory structure dies 201.

Each control die 211 is affixed (e.g., bonded) to at least one of the memory structure die 201. Some of the bond pads 282/284 are depicted. There may be many more bond pads. A space between two die 201, 211 that are bonded together is filled with a solid layer 280, which may be formed from epoxy or other resin or polymer. This solid layer 280 protects the electrical connections between the die 201, 211, and further secures the die together.

The integrated memory assembly 207 may for example be stacked with a stepped offset, leaving the bond pads at each level uncovered and accessible from above. Wire bonds 270 connected to the bond pads connect the control die 211 to the substrate 271. A number of such wire bonds may be formed across the width of each control die 211 (i.e., into the page of FIG. 2C).

A memory die through silicon via (TSV) 276 may be used to route signals through a memory structure die 201. A control die through silicon via (TSV) 278 may be used to route signals through a control die 211. The TSVs 276, 278 may be formed before, during or after formation of the integrated circuits in the semiconductor dies 201, 211. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package. The solder balls 272 may form a part of the interface between integrated memory assembly 207 and memory controller 120.

FIG. 2D depicts a side view of another embodiment of an integrated memory assembly 207 stacked on a substrate 271. The integrated memory assembly 207 of FIG. 2D has three control dies 211 and three memory structure dies 201. In some embodiments, there are many more than three memory structure dies 201 and many more than three control dies 211. In this example, each control die 211 is bonded to at least one memory structure die 201. Optionally, a control die 211 may be bonded to two or more memory structure dies 201.

Some of the bond pads 282, 284 are depicted. There may be many more bond pads. A space between two dies 201, 211 that are bonded together is filled with a solid layer 280, which may be formed from epoxy or other resin or polymer. In contrast to the example in FIG. 2C, the integrated memory assembly 207 in FIG. 2D does not have a stepped offset. A memory die through silicon via (TSV) 276 may be used to route signals through a memory structure die 201. A control die through silicon via (TSV) 278 may be used to route signals through a control die 211.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package.

As has been briefly discussed above, the control die 211 and the memory structure die 201 may be bonded together. Bond pads on each die 201, 211 may be used to bond the two die together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat may also be applied. In embodiments using Cu-to-Cu bonding, the bond pads may be about 5 μm square and spaced from each other with a pitch of 5 μm to 5 μm. While this process is referred to herein as Cu-to-Cu bonding, this term may also apply even where the bond pads are formed of materials other than Cu.

When the area of bond pads is small, it may be difficult to bond the semiconductor die together. The size of, and pitch between, bond pads may be further reduced by providing a film layer on the surfaces of the semiconductor die including the bond pads. The film layer is provided around the bond pads. When the die are brought together, the bond pads may bond to each other, and the film layers on the respective die may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller sizes and pitches.

Some embodiments may include a film on surface of the dies 201, 211. Where no such film is initially provided, a space between the die may be under filled with an epoxy or other resin or polymer. The under-fill material may be applied as a liquid which then hardens into a solid layer. This under-fill step protects the electrical connections between the dies 201, 211, and further secures the die together. Various materials may be used as under-fill material.

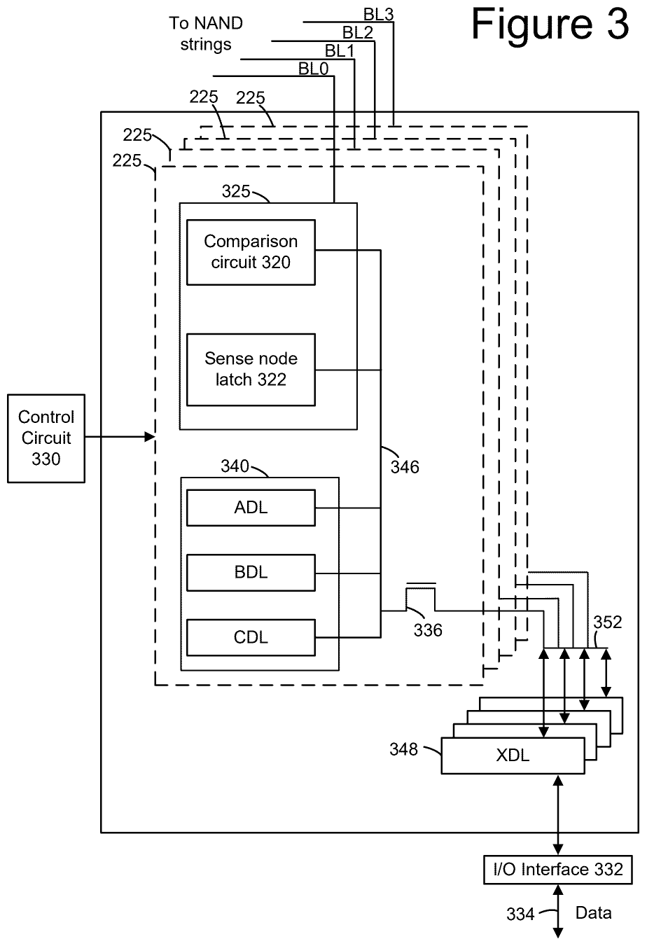

FIG. 3 is a block diagram depicting one embodiment of a portion of column control circuitry 210 that contains a number of read/write circuits 225. Each read/write circuit 225 is partitioned into a plurality of sense amplifiers 325 and data latches 340. A control circuit 330 controls the read/write circuits 225. In one embodiment, each sense amplifier 325 is connected to a respective bit line. Each bit line may be connected, at one point in time, to one of a large number of different NAND strings. A select gate on the NAND string may be used to connect the NAND string channel to the bit line.

Each sense amplifier 325 operates to provide voltages to one of the bit lines (see BL0, BL1, BL2, BL3) during program, verify, erase, and read operations. Sense amplifiers are also used to sense the condition (e.g., data state) of a memory cell in a NAND string connected to the bit line that connects to the respective sense amplifier.

Each sense amplifier 325 may have a sense node. During sensing, a sense node is charged up to an initial voltage, Vsense_init, such as 3V. The sense node is then connected to the bit line for a sensing time, and an amount of change of voltage of the sense node is used to determine whether a memory cell is in a conductive or non-conductive state. In some embodiments, the memory cell current will discharge the voltage on the sense node. In other embodiments, the memory cell current will charge the voltage on the sense node.

The amount of change of the sense node voltage also indicates whether a current Icell in the memory cell exceeds a reference current, Iref. A larger change corresponds to a larger current. If Icell<=Iref, the memory cell is in a non-conductive state and if Icell>Iref, the memory cell is in a conductive state. In an embodiment, the sense node has a capacitor that is pre-charged and then discharged for the sensing time. In an embodiment, the sense node has a capacitor that is pre-charged and then charged for the sensing time.

In particular, the comparison circuit 320 determines the amount of change of voltage on the sense node by comparing the sense node voltage to a trip voltage after the sensing time. In an embodiment if the sense node voltage decays below the trip voltage, Vtrip, the memory cell is in a conductive state and its Vth is at or below the verify voltage. In an embodiment if the sense node voltage does not decay below Vtrip, the memory cell is in a non-conductive state and its Vth is above the verify voltage. A sense node latch 322 is set to 0 or 1, for example, by the comparison circuit 320 based on whether the memory cell is in a conductive or non-conductive state, respectively. For example, in a program-verify test, a 0 can denote fail and a 1 can denote pass. The bit in the sense node latch 322 can also be used in a lockout scan to decide whether to set a bit line voltage to an inhibit or a program enable level in a next program loop.

The data latches 340 are coupled to the sense amplifier 325 by a local data bus 346. The data latches 340 include three latches (ADL, BDL, CDL) for each sense amplifier 325 in this example. More or fewer than three latches may be included in the data latches 340. In one embodiment, for programming each data latch 340 is used to store one bit to be stored into a memory cell and for reading each data latch 340 is used to store one bit read from a memory cell. In a three bit per memory cell embodiment, ADL stores a bit for a lower page of data, BDL stores a bit for a middle page of data, CDL stores a bit for an upper page of data. Each read/write circuit 225 is connected to an XDL latch 348 by way of an XDL bus 352. In this example, transistor 336 connects local data bus 346 to XDL bus 352. An I/O interface 332 is connected to the XDL latches 348. The XDL latch 348 associated with a particular read/write circuit 225 serves as an interface latch for storing/latching data from the memory controller.

Control circuit 330 performs computations, such as determining the data stored in the sensed memory cell and store the determined data in the set of data latches. Each set of data latches 340 is used to store data bits determined by control circuit 330 during a read operation, and to store data bits imported from the data bus 334 during a program operation which represent write data meant to be programmed into the memory. I/O interface 332 provides an interface between XDL latches 348 and the data bus 334.

During reading, the operation of the system is under the control of state machine 262 that controls the supply of different control gate voltages to the addressed memory cell. As it steps through the various predefined control gate voltages corresponding to the various memory states supported by the memory, the sense circuit may trip at one of these voltages and a corresponding output will be provided from the sense amplifier to control circuit 330. At that point, control circuit 330 determines the resultant memory state by consideration of the tripping event(s) of the sense circuit and the information about the applied control gate voltage from the state machine. It then computes a binary encoding for the memory state and stores the resultant data bits into data latches 340.

During program or verify operations for memory cells, the data to be programmed (write data) is stored in the set of data latches 340 from the data bus 334 by way of XDL latches 348. The program operation, under the control of the state machine 262, applies a series of programming voltage pulses to the control gates of the addressed memory cells. Each voltage pulse may be stepped up in magnitude from a previous program pulse by a step size in a process referred to as incremental step pulse programming. Each program voltage is followed by a verify operation to determine if the memory cells has been programmed to the desired memory state. In some cases, control circuit 330 monitors the read back memory state relative to the desired memory state. When the two agree, control circuit 330 sets the bit line in a program inhibit mode such as by updating its latches. This inhibits the memory cell coupled to the bit line from further programming even if additional program pulses are applied to its control gate.

FIG. 4 is a perspective view of a portion of one example embodiment of a monolithic three dimensional memory array/structure that can comprise memory structure 202, which includes a plurality non-volatile memory cells arranged as vertical NAND strings. For example, FIG. 4 shows a portion 400 of one block of memory. The structure depicted includes a set of bit lines BL positioned above a stack 401 of alternating dielectric layers and conductive layers. For example purposes, one of the dielectric layers is marked as D. The conductive layers are labeled as one of: SGD, WL, or SGS. An SGD conductive layer serves as drain side select lines. A WL conductive layer serves as a word line. An SGS conductive layer serves as a source side select line. The numbers of each of these conductive layers is limited for ease of illustration. The number of alternating dielectric layers and conductive layers can vary based on specific implementation requirements. Below the alternating dielectric layers and word line layers is a source line layer SL. Memory holes are formed in the stack of alternating dielectric layers and conductive layers. For example, one of the memory holes is marked as MH. Note that in FIG. 4, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three dimensional monolithic memory array that comprises memory structure 202 is provided below.

In one embodiment the block is operated as a number of “sub-blocks.” Each of these “sub-blocks” has many NAND strings. In an embodiment, an isolation region (IR) divides the SGD layers into multiple SGD select lines, each of which is used to select a sub-block (e.g., set of NAND strings). FIG. 4 depicts an example having one IR region and thereby two sub-blocks. However, there may be more than one IR region and thereby more than two sub-blocks. Optionally, the IR region can extend downward through all of the alternating dielectric layers and conductive layers.

FIG. 4A is a block diagram explaining one example organization of memory structure 202, which is divided into two planes 403-A and 403-B. Each plane 403 is then divided into M physical blocks. In one example, each plane has about 2000 physical blocks (or more briefly “blocks”). However, different numbers of blocks and planes can also be used. In one “full-block” embodiment, a block of memory cells is a unit of erase. That is, all memory cells of a block are erased together. In a “sub-block mode” embodiment, blocks are divided into sub-blocks and the sub-blocks are the unit of erase. In an embodiment, a block contains a number of word lines with each sub-block containing a unique set of the data word lines. In an embodiment, each plane 403-A, 403-B has a set of bit lines that extend across all of the blocks in that plane. In an embodiment, one block per plane is selected at a time. Memory cells can also be grouped into blocks for other reasons, such as to organize the memory structure to enable the signaling and selection circuits. In some embodiments, a block represents a groups of connected memory cells as the memory cells of a block share a common set of word lines. For example, the word lines for a block are all connected to all of the vertical NAND strings for that block. Although FIG. 4A shows two planes 403-A, 403-B more or fewer than two planes can be implemented. In some embodiments, memory structure 202 includes four planes. In some embodiments, memory structure 202 includes eight planes. In some embodiments, programming can be performed in parallel in a first selected block in plane 403-A and a second selected block in plane 403-B.

FIGS. 4B-4F4 depict an example three dimensional (“3D”) NAND structure that corresponds to the structure of FIG. 4 and can be used to implement memory structure 202 of FIGS. 2A and 2B. FIG. 4B is a diagram depicting a top view of a portion 407 of Block 2. As can be seen from FIG. 4B, the physical block depicted in FIG. 4B extends in the direction of arrow 433. In one embodiment, the memory array has many layers; however, FIG. 4B only shows the top layer.

FIG. 4B depicts a plurality of circles that represent the vertical columns. Each of the vertical columns include multiple select transistors (also referred to as a select gate or selection gate) and multiple memory cells. In one embodiment, each vertical column implements a NAND string. For example, FIG. 4B depicts vertical columns 422, 432, 442, and 452. Vertical column 422 implements NAND string 482. Vertical column 432 implements NAND string 484. Vertical column 442 implements NAND string 486. Vertical column 452 implements NAND string 488. More details of the vertical columns are provided below. Since the physical block depicted in FIG. 4B extends in the direction of arrow 433, the physical block includes more vertical columns than depicted in FIG. 4B.

FIG. 4B also depicts a set of bit lines 415, including bit lines 411, 412, 413, 414, . . . 419. FIG. 4B shows twenty-four bit lines because only a portion of the physical block is depicted. It is contemplated that more than twenty-four bit lines connected to vertical columns of the physical block. Each of the circles representing vertical columns has an “x” to indicate its connection to one bit line. For example, bit line 414 is connected to vertical columns 422, 432, 442 and 452.

The physical block depicted in FIG. 4B includes a set of isolation regions 402, 404, 406, 408, and 410, which are formed of SiO₂; however, other dielectric materials can also be used. Isolation regions 402, 404, 406, 408, and 410 serve to divide the top layers of the physical block into four regions; for example, the top layer depicted in FIG. 4B is divided into regions 420, 430, 440, and 450, which are referred to herein as “sub-blocks. Each sub-block contains a large number of NAND strings. In one embodiment, isolation regions 402 and 410 separate the physical block 407 from adjacent physical blocks. Thus, isolation regions 402 and 410 may extend down to the substrate. In one embodiment, the isolation regions 404, 406, and 408 only divide the layers used to implement select gates so that NAND strings in different sub-blocks can be independently selected. Referring back to FIG. 4, the IR region may correspond to any of isolation regions 404, 406, or 408. In one example implementation, a bit line only connects to one vertical column/NAND string in each of regions (sub-blocks) 420, 430, 440, and 450. In that implementation, each physical block has sixteen rows of active columns and each bit line connects to four NAND strings in each block. In one embodiment, all of the four vertical columns/NAND strings connected to a common bit line are connected to the same word line (or set of word lines); therefore, the system uses the drain side selection lines to choose one (or another subset) of the four to be subjected to a memory operation (program, verify, read, and/or erase).

Although FIG. 4B shows each region (420, 430, 440, 450) having four rows of vertical columns, four regions (420, 430, 440, 450) and sixteen rows of vertical columns in a block, those exact numbers are an example implementation. Other embodiments may include more or fewer regions (420, 430, 440, 450) per block, more or fewer rows of vertical columns per region and more or fewer rows of vertical columns per block. FIG. 4B also shows the vertical columns being staggered. In other embodiments, different patterns of staggering can be used. In some embodiments, the vertical columns are not staggered.

FIG. 4C depicts an example of a stack 435 showing a cross-sectional view along line AA of FIG. 4B. The SGD layers include SGDT0, SGDT1, SGD0, and SGD1. The SGD layers may have more or fewer than four layers. The SGS layers includes SGSB0, SGSB1, SGS0, and SGS1. The SGS layers may have more or fewer than four layers. Six dummy word line layers DD0, DD1, WLIFDU, WLIDDL, DS1, and DS0 are provided, in addition to the data word line layers WL0-WL111. There may be more or fewer than 112 data word line layers and more or fewer than six dummy word line layers. Each NAND string has a drain side select gate at the SGD layers. Each NAND string has a source side select gate at the SGS layers. Also depicted are dielectric layers DL0-DL124.

Columns 432, 434 of memory cells are depicted in the multi-layer stack. The stack includes a substrate 457, an insulating film 454 on the substrate, and a portion of a source line SL. A portion of the bit line 414 is also depicted. Note that NAND string 484 is connected to the bit line 414. NAND string 484 has a source-end at a bottom of the stack and a drain-end at a top of the stack. The source-end is connected to the source line SL. A conductive via 429 connects the drain-end of NAND string 484 to the bit line 414.

In one embodiment, the memory cells are arranged in NAND strings. The word line layers WL0-WL111 connect to memory cells (also called data memory cells). Dummy word line layers DD0, DD1, DS0 and DS1 connect to dummy memory cells. A dummy memory cell does not store and is not eligible to store host data (data provided from the host, such as data from a user of the host), while a data memory cell is eligible to store host data. In some embodiments, data memory cells and dummy memory cells may have the same structure. Drain side select layers SGD are used to electrically connect and disconnect (or cut off) the channels of respective NAND strings from bit lines. Source side select layers SGS are used to electrically connect and disconnect (or cut off) the channels of respective NAND strings from the source line SL.

FIG. 4C depicts an example of a stack 435 having two tiers (lower tier 423, upper tier 421). A two tier or other multi-tier stack can be used to form a relatively tall stack while maintaining a relatively narrow memory hole width (or diameter). After the layers of the lower tier are formed, memory hole portions are formed in the lower tier. Subsequently, after the layers of the upper tier are formed, memory hole portions are formed in the upper tier, aligned with the memory hole portions in the lower tier to form continuous memory holes from the bottom to the top of the stack. The resulting memory hole is narrower than would be the case if the hole were etched from the top to the bottom of the stack rather than in each tier individually. An interface (IF) region is created where the two tiers are connected. The IF region is typically thicker than the other dielectric layers. Due to the presence of the IF region, the adjacent word line layers suffer from edge effects such as difficulty in programming or erasing. These adjacent word line layers can therefore be set as dummy word lines (WLIFDL, WLIFDU). In some embodiments, the tiers are erased independent of one another. Hence, data may be maintained in the upper tier 421 after the lower tier 423 is erased. Likewise, data may be maintained in the lower tier 423 after upper tier 421 is erased.

FIG. 4D depicts a view of the region 445 of FIG. 4C. Data memory cell transistors 520, 521, 522, 523, and 524 are indicated by the dashed lines. A number of layers can be deposited along the sidewall (SW) of the memory hole 432 and/or within each word line layer, e.g., using atomic layer deposition. For example, each column (e.g., the pillar which is formed by the materials within a memory hole) can include a blocking oxide/block high-k material 470, charge-trapping layer or film 463 such as SiN or other nitride, a tunneling layer 464, a polysilicon body or channel 465, and a dielectric core 466. A word line layer can include a conductive metal 462 such as Tungsten as a control gate. For example, control gates 490, 491, 492, 493 and 494 are provided. In this example, all of the layers except the metal are provided in the memory hole. In other approaches, some of the layers can be in the control gate layer. Additional pillars are similarly formed in the different memory holes. A pillar can form a columnar active area (AA) of a NAND string.

When a data memory cell transistor is programmed, electrons are stored in a portion of the charge-trapping layer which is associated with the data memory cell transistor. These electrons are drawn into the charge-trapping layer from the channel, and through the tunneling layer. The Vt of a data memory cell transistor is increased in proportion to the amount of stored charge. During an erase operation, the electrons return to the channel.

Each of the memory holes can be filled with a plurality of annular layers (also referred to as memory film layers) comprising a blocking oxide layer, a charge trapping layer, a tunneling layer and a channel layer. A core region of each of the memory holes is filled with a body material, and the plurality of annular layers are between the core region and the WLLs in each of the memory holes. In some cases, the tunneling layer 464 can comprise multiple layers such as in an oxide-nitride-oxide configuration.

FIG. 4E is a schematic diagram of a portion of the memory array 202. FIG. 4E shows physical data word lines WL0-WL111 running in the x-direction. The physical data word lines WL0-WL111 may also extend in the y-direction across the entire extent of the block. Therefore, each word line connects to many more NAND strings in the block. The structure of FIG. 4E corresponds to a portion 407 in Block 2 of FIG. 4A, including bit line 411. Within the physical block, in one embodiment, each bit line is connected to four NAND strings. Thus, FIG. 4E shows bit line 411 connected to NAND string NS0, NAND string NS1, NAND string NS2, and NAND string NS3.

In one embodiment, there are four sets of drain side select lines in the physical block. For example, the set of drain side select lines connected to NS0 include SGDT0-s0, SGDT1-s0, SGD0-s0, and SGD1-s0. Each of these drain side select lines SGDT0-s0, SGDT1-s0, SGD0-s0, and SGD1-s0 extends in the y-direction across the entire extent of the block such that each drain side select line connects to many NAND strings in the block. The set of drain side select lines connected to NS1 include SGDT0-s1, SGDT1-s1, SGD0-s1, and SGD1-s1. The set of drain side select lines connected to NS2 include SGDT0-s2, SGDT1-s2, SGD0-s2, and SGD1-s2. The set of drain side select lines connected to NS3 include SGDT0-s3, SGDT1-s3, SGD0-s3, and SGD1-s3. Herein the term “SGD” may be used as a general term to refer to any one or more of the lines in a set of drain side select lines. In some embodiments, the same operating voltage is applied to SGDT0 and SGDT1. In some embodiments, the same operating voltage is applied to SGD0 and SGD1. In some erase embodiments, different operating voltage are applied to SGDT0/SGDT1 than to SGD0/SGD1. Note that SGDT0/SGDT1 are adjacent to the bit line. In some erase embodiments, a voltage applied to SGDT0/SGDT1 in combination with a bit line voltage may be used to generate a gate induced gate leakage (GIDL) current. Such a voltage applied to SGDT0/SGDT1 may be referred to herein as a GIDL voltage.

In an embodiment, each line in a given set may be operated independent from the other lines in that set to allow for different voltages to the gates of the four drain side select transistors on the NAND string. Moreover, each set of drain side select lines can be selected independent of the other sets. Each set drain side select lines connects to a group of NAND strings in the block. Only one NAND string of each group is depicted in FIG. 4E. These four sets of drain side select lines correspond to four “sub-blocks.” A first sub-block corresponds to those vertical NAND strings controlled by SGDT0-s0, SGDT1-s0, SGD0-s0, and SGD1-s0. A second sub-block corresponds to those vertical NAND strings controlled by SGDT0-s1, SGDT1-s1, SGD0-s1, and SGD1-s1. A third sub-block corresponds to those vertical NAND strings controlled by SGDT0-s2, SGDT1-s2, SGD0-s2, and SGD1-s2. A fourth sub-block corresponds to those vertical NAND strings controlled by SGDT0-s3, SGDT1-s3, SGD0-s3, and SGD1-s3. As noted, FIG. 4E only shows the NAND strings connected to bit line 411. However, a full schematic of the block would show every bit line and four vertical NAND strings connected to each bit line.

FIG. 4F1-4F4 are schematic diagrams of a portion of the memory array 202, along with sense amplifiers. The NAND strings in FIG. 4F1-4F4 correspond to those in a single sub-block within a block. FIG. 4F1 shows physical data word lines WL0-WL111 running in the y-direction (the x-y-z axes apply to only the NAND strings and bit lines). Two sets of NAND strings 501-A, 501-B are depicted. Only two of the many NAND strings are depicted for each set. There may be hundreds or thousands of NAND strings in each set 501. As one example, there are 8K NAND strings in each set 501-A, 501-B. Each word line connects to a memory cell on each of the NAND strings in set 501-A and in set 501-B, in the example in FIG. 4F1. Each NAND string in both sets 501-A, 501-B is connected to a common source line (SL). Each NAND string is connected to a bit line. The first set of NAND strings 501-A are connected to bit lines BL0-BLm. The second set of NAND strings 501-B are connected to bit lines BLm+1-BLn. Each bit line is associated with a sense amplifier (SA) 325. Therefore, each SA 325 in the first set of SA 325-A is configured to sense memory cells on one of the NAND strings in the first set of NAND strings 501-A. Likewise, each SA 325 in the second set of SA 325-B is configured to sense memory cells on one of the NAND strings in the first set of NAND strings 501-A. Each bit line is also connected to many other NAND strings, whereby each SA 325 can sense memory cells on other NAND strings at a different time. The drain side select gates (SGDT0, SGDT1, SGD0, SGD1) may be used to connect the NAND channel to the bit line such that the SA 325 may sense a current in the NAND string channel that flows in the bit line. The memory system may read one selected memory cell on each of the NAND strings during a read operation (or verify operation) within the sub-block.

FIG. 4F2 shows a variation on the architecture of FIG. 4F1. Recall that in FIG. 4F1, all NAND strings in each set 501-A and 501-B connect to a common source line (SL). However, in FIG. 4F2 there are two separate source lines (SL-A, SL-B). Each NAND string in set 501-A connects to source line SL-A. Each NAND string in set 501-B connects to source line SL-B. Similar to FIG. 4F1, the physical data word lines WL0-WL111 run in the y-direction (the x-y-z axes apply to only the NAND strings and bit lines). Moreover, each word line connects to a memory cell on each of the NAND strings in set 501-A and in set 501-B.

FIG. 4F3 shows a variation on the architecture of FIG. 4F1 and 4F2. Similar to the architecture in FIG. 4F2, there are two separate source lines (SL-A, SL-B). Each NAND string in set 501-A connects to source line SL-A. Each NAND string in NAND string set 501-B connects to source line SL-B. However, the word lines are also in a split configuration. The word lines have a first segment (A) and a second segment (B) with each segment connected to one of the NAND string sets 501-A or 501-B. For example, WL111-A connects to a memory cell on each NAND string in NAND string set 501-A, whereas WL111-B connects to a memory cell on each NAND string in NAND string set 501-B. WL111-A segment and WL111-B segments may be driven by separate WL drivers. Therefore, if the memory system is reading cells on WL111-A and WL111-B at the same time, the memory system may apply a different voltage to WL111-A than to WL111-B. In some embodiment, the memory system will select a different numbered word line to read for NAND string set 501-A than NAND string set 501-B. As will be explained in more detail below, this can be beneficial if the memory cell current is flowing from bit lines to source line in one set of NAND strings, but is flowing from source line to bit lines in the other set of NAND strings.

FIG. 4F4 shows still another variation on the architectures of FIG. 4F1, 4F2, and 4F3. Similar to the architecture in FIG. 4F3 the word lines are in a split configuration. However, in FIG. 4F4 there is a single source line (SL) that connects to all NAND strings in both NAND string sets 501-A and 501-B.

Although the example memories of FIGS. 4-4F4 are three dimensional memory structure that includes vertical NAND strings with charge-trapping material, other 3D memory structures can also be used with the technology described herein.

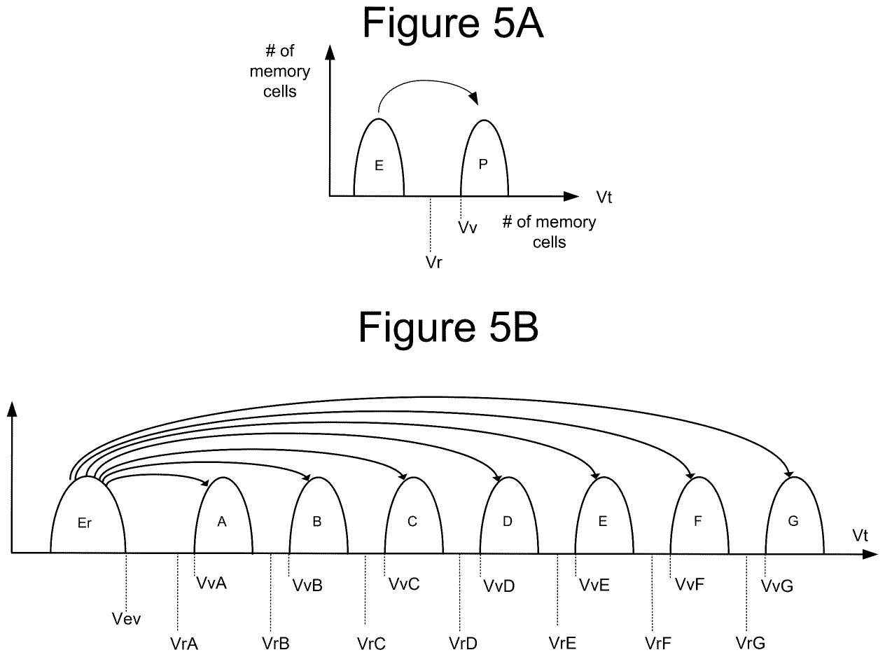

The storage systems discussed above can be erased, programmed and read. At the end of a successful programming process, the threshold voltages of the memory cells should be within one or more distributions of threshold voltages for programmed memory cells or within a distribution of threshold voltages for erased memory cells, as appropriate. FIG. 5A is a graph of threshold voltage versus number of memory cells, and illustrates example threshold voltage distributions for the memory array when each memory cell stores one bit of data per memory cell. Memory cells that store one bit of data per memory cell data are referred to as single level cells (“SLC”). The data stored in SLC memory cells is referred to as SLC data; therefore, SLC data comprises one bit per memory cell. Data stored as one bit per memory cell is SLC data. FIG. 5A shows two threshold voltage distributions: E and P. Threshold voltage distribution E corresponds to an erased data state. Threshold voltage distribution P corresponds to a programmed data state. Memory cells that have threshold voltages in threshold voltage distribution E are, therefore, in the erased data state (e.g., they are erased). Memory cells that have threshold voltages in threshold voltage distribution P are, therefore, in the programmed data state (e.g., they are programmed). In one embodiment, erased memory cells store data “1” and programmed memory cells store data “0.” FIG. 5A depicts read reference voltage Vr. By testing (e.g., performing one or more sense operations) whether the threshold voltage of a given memory cell is above or below Vr, the system can determine whether a memory cells is erased (state E) or programmed (state P). FIG. 5A also depicts verify reference voltage Vv. In some embodiments, when programming memory cells to data state P, the system will test whether those memory cells have a threshold voltage greater than or equal to Vv.

Memory cells that store multiple bit per memory cell data are referred to as multi-level cells (“MLC”). The data stored in MLC memory cells is referred to as MLC data; therefore, MLC data comprises multiple bits per memory cell. Data stored as multiple bits of data per memory cell is MLC data. In the example embodiment of FIG. 5B, each memory cell stores three bits of data. Other embodiments may use other data capacities per memory cell (e.g., such as two, four, or five bits of data per memory cell).

FIG. 5B shows eight threshold voltage distributions, corresponding to eight data states. The first threshold voltage distribution (data state) Er represents memory cells that are erased. The other seven threshold voltage distributions (data states) A-G represent memory cells that are programmed and, therefore, are also called programmed states. Each threshold voltage distribution (data state) corresponds to predetermined values for the set of data bits. The specific relationship between the data programmed into the memory cell and the threshold voltage levels of the cell depends upon the data encoding scheme adopted for the cells. In one embodiment, data values are assigned to the threshold voltage ranges using a Gray code assignment so that if the threshold voltage of a memory erroneously shifts to its neighboring physical state, only one bit will be affected.

FIG. 5B shows seven read reference voltages, VrA, VrB, VrC, VrD, VrE, VrF, and VrG for reading data from memory cells. By testing (e.g., performing sense operations) whether the threshold voltage of a given memory cell is above or below the seven read reference voltages, the system can determine what data state (i.e., A, B, C, D, . . . ) a memory cell is in. FIG. 5B also shows a number of verify reference voltages. The verify high voltages are VvA, VvB, VvC, VvD, VvE, VvF, and VvG. In some embodiments, when programming memory cells to data state A, the system will test whether those memory cells have a threshold voltage greater than or equal to VvA. If the memory cell has a threshold voltage greater than or equal to VvA, then the memory cell is locked out from further programming. Similar reasoning applies to the other data states.

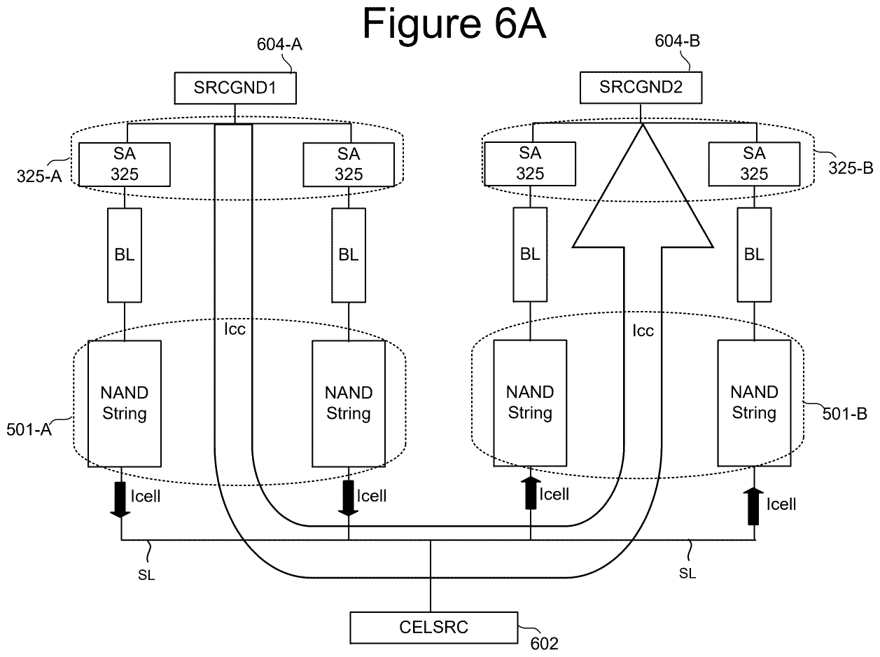

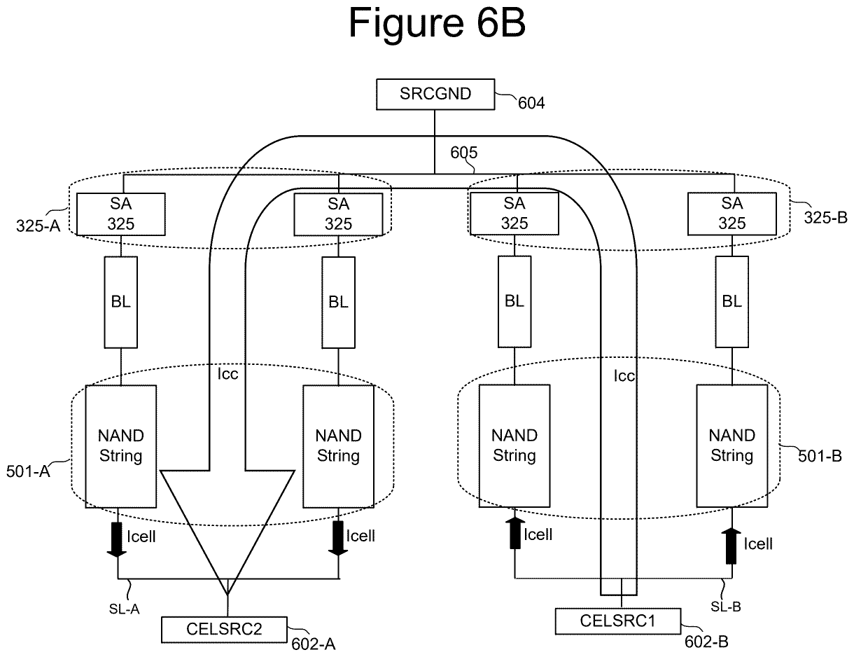

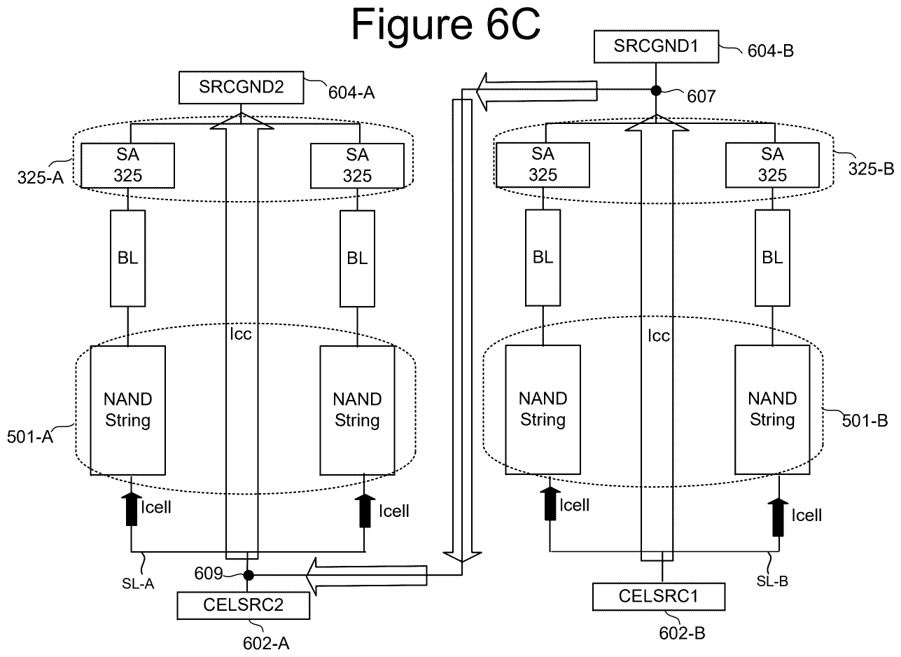

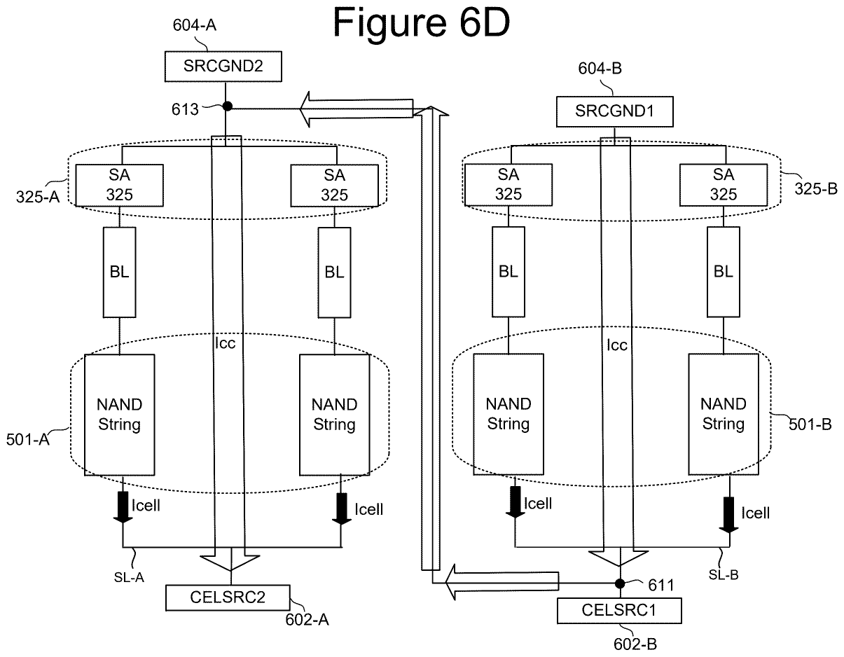

FIG. 6A is a diagram illustrating a portion of an embodiment of a memory system that recycles current during a sense operation (e.g., read, verify) of non-volatile memory cells. Two sets of NAND strings 501-A, 501-B and two sets of SA 325-A, 325-B are depicted. The two sets of NAND strings 501-A, 501-B each connect to a common source line (SL). The SL is connected to a voltage source CELSRC 602. The terms “CELSRC” of “Vcelsrc” may be used to refer to the voltage provided by the voltage source CELSRC 602. Each SA 325 in the first set of SA 325-A is connected to a voltage source SRCGND1 604-A. Each SA 325 in the second set of SA 325-B is connected to a voltage source SRCGND2 604-B. During the sense operation the memory cell current (Icell) for NAND strings 501-A flows from the bit lines to the source line. Therefore, each SA 325 in the first set of SA 325-A is configured to sense with an assumption that memory cell current flows from bit line to source line. Also, each SA 325 in the first set of SA 325-A is configured to charge its bit line to a voltage that is higher than CELSRC. The voltage source SRCGND1 604-A may be used to charge the bit lines connected to the first set of SA 325-A. However, during the sense operation the memory cell current (Icell) for NAND strings 501-B flows from the source line to the bit lines. Therefore, each SA 325 in the second set of SA 325-B is configured to sense with an assumption that memory cell current flows from source line to bit line. Also, each SA 325 in the second set of SA 325-B is configured to charge its bit line to a voltage that is lower than CELSRC. The voltage source SRCGND2 604-B may be used to charge the bit lines connected to the second set of SA 325-B. In one embodiment, the architecture depicted in FIG. 4F1 is used in the system in FIG. 6A. In one embodiment, the architecture depicted in FIG. 4F4 is used in the system in FIG. 6A.

During the sense operation, the memory system applies a reference voltage to the control gate of the selected memory cells while applying a read pass voltage to the control gates of other memory cells (“unselected memory cells”) on the NAND strings. The read pass voltage has a sufficiently high magnitude to be above the highest Vt of any of the unselected memory cells. Thus, the unselected memory cells should each turn on. The selected memory cell might or might not turn on and conduct a significant current (Icell), depending on its Vt. The bit line current may be sensed to determine the state of the selected memory cell. The Icells of the selected memory cells in the first set 501-A flows to the source line (SL) and is recycled back to the second set of NAND strings 501-B. Recycling the Icell substantially reduces the collective Icc during at least a portion of the sense operation. For example, there may be about 8K NAND strings in the first set 501-A and another 8K NAND strings in the second set 501-B. Conventionally, the Icell of the memory cells in the second set of NAND strings 501-B may flow from bit line to source line (similar to the first set of NAND strings 501-A). Such conventional sensing may thus consume far greater Icc, as all Icell flows from the bit lines to the source line.

FIG. 6B is a diagram illustrating a portion of an embodiment of a memory system that recycles current during a sense operation (e.g., read, verify) of non-volatile memory cells. Two set of NAND strings 501-A, 501-B and two sets of SA 325-A, 325-B are depicted. NAND strings 501-A connect to a first source line (SL-A). The SL-A is connected to a voltage source CELSRC2 602-A. NAND strings 501-B connect to a second source line (SL-B). The SL-B is connected to a voltage source CELSRC1 602-B. Each SA 325 in the first set of SA 325-A and each SA 325 in the second set of SA 325-B is connected to a voltage source SRCGND 604. During the sense operation the memory cell current (Icell) for NAND strings 501-A flows from the bit lines to the source line. Therefore, each SA 325 in the first set of SA 325-A is configured to sense with an assumption that memory cell current flows from bit line to source line. Also, each SA 325 in the first set of SA 325-A is configured to charge its bit line to a voltage that is higher than CELSRC2. The voltage source SRCGND 604 may be used to charge the bit lines connected to the first set of SA 325-A. However, during the sense operation the memory cell current (Icell) for NAND strings 501-B flows from the source line (SL-B) to the bit lines. Therefore, each SA 325 in the second set of SA 325-B is configured to sense with an assumption that memory cell current flows from source line SL-B to bit line. Also, each SA 325 in the second set of SA 325-B is configured to charge its bit line to a voltage that is lower than CELSRC1. The voltage source SRCGND 604 may be used to charge the bit lines connected to the second set of SA 325-B. In one embodiment, the architecture depicted in FIG. 4F2 is used in the system in FIG. 6B. In one embodiment, the architecture depicted in FIG. 4F3 is used in the system in FIG. 6B.

During the sense operation, CELCRC1 602-B provides the current for the Icells of the selected memory cells in second set of NAND strings 501-B. The current is recycled through the common connection 605 of the SA 325-A and SA 325-B to SRCGND 604. The Icells of the selected memory cells in the first set 501-A flow to the source line (SL-A). Recycling the Icell substantially reduces the collective Icc during at least a portion of the sense operation.

FIG. 6C is a diagram illustrating a portion of an embodiment of a memory system that recycles current during a sense operation (e.g., read, verify) of non-volatile memory cells. Two set of NAND strings 501-A, 501-B and two sets of SA 325-A, 325-B are depicted. NAND strings 501-A connect to a first source line (SL-A). The SL-A is connected to a voltage source CELSRC2 602-A. NAND strings 501-B connect to a second source line (SL-B). The SL-B is connected to a voltage source CELSRC1 602-B. Each SA 325 in the first set of SA 325-A is connected to a voltage source SRCGND2 604-A. During the sense operation the memory cell current (Icell) for NAND strings 501-A flows from the source line SL-A to the bit lines. Therefore, each SA 325 in the first set of SA 325-A is configured to sense with an assumption that memory cell current flows from source line SL-A to bit lines. Also, each SA 325 in the first set of SA 325-A is configured to charge its bit line to a voltage that is lower than CELSRC2. The voltage source SRCGND2 604-A may be used to charge the bit lines connected to the first set of SA 325-A. Each SA 325 in the second set of SA 325-A is connected to a voltage source SRCGND1 604-B. During the sense operation the memory cell current (Icell) for NAND strings 501-B flows from the source line (SL-B) to the bit lines. Therefore, each SA 325 in the second set of SA 325-B is configured to sense with an assumption that memory cell current flows from source line SL-B to bit line. Also, each SA 325 in the second set of SA 325-B is configured to charge its bit line to a voltage that is lower than CELSRC1. The voltage source SRCGND1 604-B may be used to charge the bit lines connected to the second set of SA 325-B. In one embodiment, the architecture depicted in FIG. 4F2 is used in the system in FIG. 6B. In one embodiment, the architecture depicted in FIG. 4F3 is used in the system in FIG. 6B.

Note that there is a connection between node 607 (connected to SRCGND1 604-B and the SA 325-B) and node 609 (connected to CELSRC2 602-A and SL-A). During the sense operation, CELCRC2 602-B provides the current for the Icells of the selected memory cells in second set of NAND strings 501-B. The current is recycled through the pathway node 607 to node 609 (to the source line SL-A). The Icells of the selected memory cells in the first set 501-A flow from the source line (SL-A) to the SA 325-A. Recycling the Icell substantially reduces the collective Icc during at least a portion of the sense operation.

FIG. 6D is a diagram illustrating a portion of an embodiment of a memory system that recycles current during a sense operation (e.g., read, verify) of non-volatile memory cells. Two set of NAND strings 501-A, 501-B and two sets of SA 325-A, 325-B are depicted. NAND strings 501-A connect to a first source line (SL-A). The SL-A is connected to a voltage source CELSRC2 602-A. NAND strings 501-B connect to a second source line (SL-B). The SL-B is connected to a voltage source CELSRC1 602-B. Each SA 325 in the first set of SA 325-A is connected to a voltage source SRCGND2 604-A. During the sense operation the memory cell current (Icell) for NAND strings 501-A flows from the bit lines to the source line SL-A. Therefore, each SA 325 in the first set of SA 325-A is configured to sense with an assumption that memory cell current flows from bit line to source line SL-A. Also, each SA 325 in the first set of SA 325-A is configured to charge its bit line to a voltage that is higher than CELSRC2. The voltage source SRCGND1 604-A may be used to charge the bit lines connected to the first set of SA 325-A. Each SA 325 in the second set of SA 325-B is connected to a voltage source SRCGND1 604-B. During the sense operation the memory cell current (Icell) for NAND strings 501-B flows from the bit lines to the source line (SL-B). Therefore, each SA 325 in the second set of SA 325-B is configured to sense with an assumption that memory cell current flows from bit line to source line SL-B. Also, each SA 325 in the second set of SA 325-B is configured to charge its bit line to a voltage that is higher than CELSRC1. The voltage source SRCGND1 604-B may be used to charge the bit lines connected to the second set of SA 325-B. In one embodiment, the architecture depicted in FIG. 4F2 is used in the system in FIG. 6B. In one embodiment, the architecture depicted in FIG. 4F3 is used in the system in FIG. 6B.

Note that there is a connection between node 611 (connected to CELSRC1 602-B) and node 613 (connected to SRCGND2 604-A). During the sense operation, the Icell from the second set of NAND strings 501-B flows to node 611, to node 613, and to the first set of NAND strings 501-A. The Icells of the selected memory cells in the first set 501-A flow to the source line (SL-A). Recycling the Icell substantially reduces the collective Icc during at least a portion of the sense operation.

The current recycling techniques depicted in FIGS. 6A-6D can be extended to three or more sets of NAND strings. For example, in FIG. 6A after the current has recycled up to SRCGND, the current could be recycled down a third set of NAND strings similar to how the current is recycled down from SRCGND in FIG. 6B. Many other variations are also possible. For example, concepts in FIGS. 6A-6D can be combined with each other to recycle current in three or more sets of NAND strings.

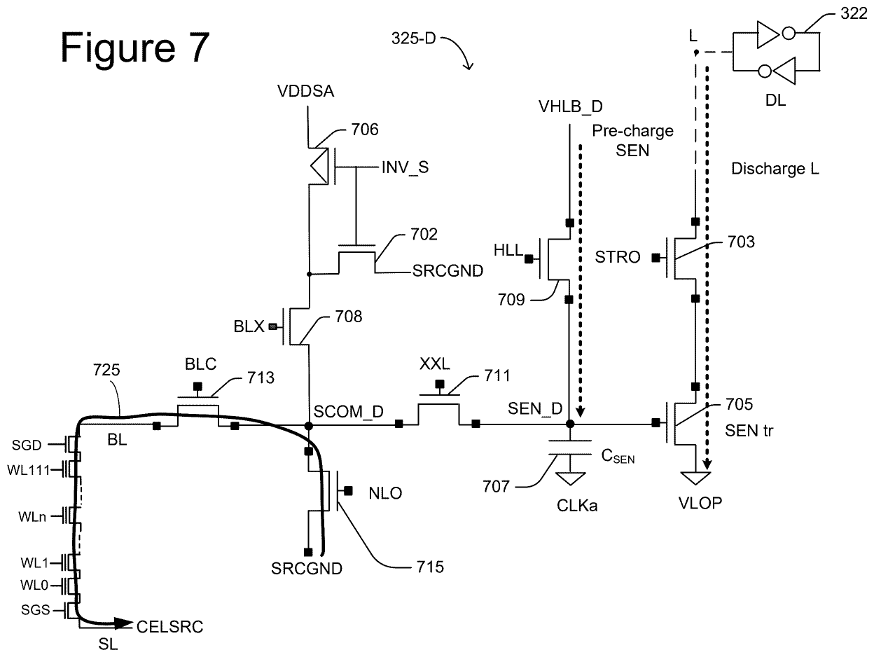

FIG. 7 is a schematic diagram of one example of a sense amplifier 325-D that may be used when sensing a memory cell having a current that flows from bit line to source line. The sense amplifier 325-D has a sense node SEN_D that is discharged by the memory cell current when sensing the memory cell. The SCOM_D node between XXL transistor 711 and BLC transistor 713 can be clamped by NLO transistor 715 and may behave the same as the BLC transistor 713. To charge the bit line, NLO transistor 715 is turned on (by taking NLO signal high) while the BLC transistor 713 is on (by taking BLC signal high). At this time, the BLX transistor 708 and the XXL transistor 711 are off. A current path 725 from SRCGND to CELSRC is depicted. The node connected to SRCGND may be referred to as a charging node due to its role in charging the bit line.

During sensing the BLC transistor 713 may be operated as a source follower to clamp the bit line at a sensing voltage. One condition to operate as a source-follower is for the voltage at the control gate of BLC transistor 713 to be lower than the voltage on the drain. When acting as a source-follower the bit line voltage is set or clamped at Vblc-Vth, where Vblc is the voltage on the control gate and Vth, e.g., 0.7 V, is the threshold voltage of the BLC transistor 713. This assumes the source line (SL) is at 0 V. The source line voltage is referred to herein as Vcelsrc. If Vcelsrc is non-zero, the bit line voltage is clamped at Vblc-Vcelsrc-Vth. The transistor 713 is therefore sometimes referred to as a bit line clamp (BLC) transistor, and the voltage Vblc on the control gate may be referred to as a bit line clamp voltage. The source-follower mode can be used during sensing operations such as read and verify operations. To provide Vsense, e.g., 0.8 V, on the bit line, the control gate of BLC transistor 713 may be set to Vsense+Vth, e.g., 1.5 V.

Basic operation of the sense amplifier 325-D when sensing a memory cell will now be discussed. The voltage level on the SEN_D node is set by pre-charging SEN_D to VHLP_D through HLL transistor 709, after which it is connected to a selected bit line by way of the XXL transistor 711 and BLC transistor 713. The current of the bit line will depend on whether the memory cell's Vt relative to the reference voltage applied to the memory cell. The bit line current may discharge SEN_D due to the direction of Icell. Thus, if the memory cell is conductive, then SEN_D is discharged. If the memory cell is not conductive, then SEN_D is not discharged.

The sense transistor (SEN tr) 705 is used to test the magnitude of the voltage on SEN_D. Specifically, a strobe transistor 703 is turned on by STRO to test the magnitude of the voltage on SEN_D. The latch 322 represents the sense node latch 322 (see FIG. 3). The value of the latch 322 is determined by the voltage level on the node L, where the node L may be pre-charged to the high VSENP level and then, depending on the voltage level on the SEN_D node, either discharged or not through the transistor SEN tr 705 to the node VLOP during a strobe operation when the transistor STRO 703 is turned on. As noted, the voltage level on the SEN_D node is pre-charged to VHLB_D through HLL transistor 709, after which it is connected to a selected bit line.

To hold charge on the SEN_D node, a sensing capacitor Cₛₑₙ 707 is connected to the SEN_D node, with its lower plate connect to the level CLKa. As illustrated by the broken line arrows, the upper plate of Cₛₑₙ 707 can be pre-charged by way of the pre-charge transistor HLL transistor 709, and then discharged to a selected memory cell along a corresponding bit line by an amount depending on how much current passes through the selected memory cell to set a voltage level on SEN_D. The level on SEN_D will then control the amount of current discharged from the node L, and the state latched in DL 322, by way of the sensing transistor SEN tr 705.

FIG. 7 also depicts transistors that may be used to charge the bit line during programming. There are two charging paths for charging the bit line. A first path allows the bit line to be charged to VDDSA by a path through transistor 706, BLX transistor 708, BLC transistor 713. A second path allows the bit line to be charged to SRCGND by a path through transistor 702, BLX transistor 708, and BLC transistor 713. In some embodiments, the bit line is charged to VDSSA to inhibit programming or SRCGND to enable programming. Based on voltages at the control gate and drain of the BLC transistor 713, the BLC transistor can operate as a pass gate or as a bit line clamp. When the voltage at the control gate is sufficiently higher than the voltage on the drain, BLC transistor 713 operates as a pass gate. For example, a program-inhibit voltage such as 2.2 V (e.g., VDSSA) may be passed to the bit line when pre-charging and inhibiting an unselected NAND string. Or, a program-enable voltage such as 0V (e.g., SRCGND) may be passed to the bit line to allow programming in a selected NAND string.

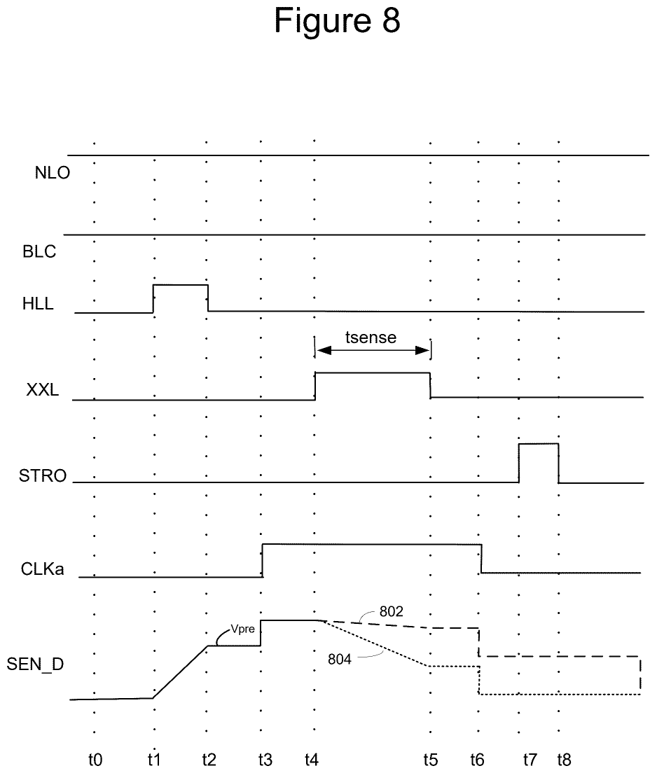

FIG. 8 depicts timing signals in sense amplifier 325 of FIG. 7 in connection with an embodiment of sensing a memory cell. The NLO signal is high throughout the time periods depicted in FIG. 8. Likewise, The BLC signal is high throughout the time periods depicted in FIG. 8.

Between t1 and t2, HLL is raised high to pre-charge the sense node SEN_D. As a result, the voltage at SEN_D is charged to the pre-charge voltage Vpre (e.g., VHLB_D). At time t2, HLL goes low, which turns off HLL transistor 709 to stop the pre-charging.

At time t3 the clock signal CLKa is raised. This has the effect of raising the voltage at SEN_D by a similar amount. Referring to FIG. 7, raising CLKa at the bottom plate of capacitor 707 has the effect of raising the top plate of the capacitor 707 (or sense node SEN_D) by a similar amount. Thus, after time t3, a sensing voltage has been established on the SEN_D node. Also, the word line voltage (not depicted in FIG. 8) has been established at a target reference level. Also, the source line voltage (not depicted in FIG. 8) has been provided to the source line. Also, the bit line voltage (not depicted in FIG. 8) has been clamped by BLC transistor 713 to a target voltage.

Referring to FIG. 8, at t4, the signal XXL goes high. Also note that BLC may be high at this time. Referring now to FIG. 7, XXL is provided to the gate of XXL transistor 711, thus turning on XXL transistor 711. Also, BLC transistor 713 is on at this time. This connects the sense node SEN_D to the bit line. The capacitor 707 is allowed to discharge its charge through the bit line and NAND string (including the selected memory cell being sensed). The managing circuit will wait for a sensing time (tsense). Referring to FIG. 7, the signal XXL remains high from t4 to t5. Also referring to FIG. 8, between t4 and t5, the sense node SEN_D discharges. Two different discharge rates are depicted. Plot 802 is associated with a memory cell having a low conduction current, and plot 804 is associated with a memory cell having a high conduction current. Stated another way, plot 802 is associated with a memory cell having a threshold voltage above the reference level. Plot 804 is associated with a memory cell having a threshold voltage below the reference level. Referring to FIG. 8, at t6 the clock signal CLKa is lowered. This has the effect of lowering the voltage at SEN by a similar amount.

Next, the voltage on the capacitor 707 is tested. The managing circuit will calculate the change in voltage across the capacitor 707 from the pre-charge voltage to the voltage after t6 (after the CLKa was lowered). Referring to FIG. 8, at t7, the strobe signal STRO goes high. Referring to FIG. 7, the sense transistor 705 will be either on or off in response to the voltage on the sense node SEN_D. With the strobe signal STRO high, transistor 703 is on, which provides a current path between the sense transistor 705 and the latch circuit 322. The latch circuit 322 will be set based on whether the sense transistor 705 conducts.

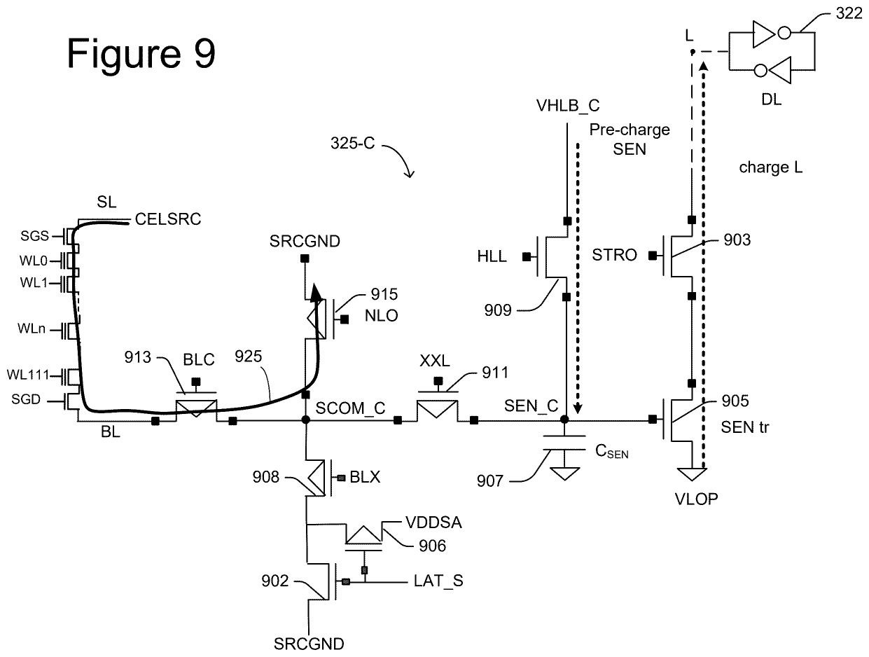

FIG. 9 is a schematic diagram of one example of a sense amplifier 325-C that may be used when sensing a memory cell having a current that flows from source line to bit line. Sense amplifier 325-C has a sense node SEN_C that may be charged by current of the memory cell being sensed. The SCOM_C node between XXL transistor 911 and BLC transistor 913 can be clamped by NLO transistor 915. To charge the bit line, NLO transistor 915 is turned on (by taking NLO signal high) while the BLC transistor 913 is on (by taking BLC signal high). At this time, the BLX transistor 908 and the XXL transistor 911 are off. A current path 925 from CELSRC to SRCGND is depicted. CELSRC may be referred to as a charging node due to its role in charging the bit line.

During sensing the BLC transistor 913 may clamp the bit line at a sensing voltage (e.g., 1V). Note that SCOM_C may be clamped by the NLO transistor 915. For example, if Vth of the BLC transistor 913 is −0.7V, to set the bit line at 1V, the BLC signal may be 0.3V (1 V 0.7V). To set SCOM_C to 0.5V, the NLO signal may be −0.2V (0.5 V-0.7V).

Basic operation of the sense amplifier 325-C when sensing a memory cell will now be discussed. The voltage level on the SEN_C node may be pre-charged by pre-charging SEN_C to VHLB_C through HLL transistor 909, after which it is connected to a selected bit line by way of the XXL transistor 911 and BLC transistor 913. The current of the bit line will depend on whether the memory cell's Vt relative to the reference voltage applied to the memory cell. The bit line current may charge SEN due to the direction of Icell. Thus, if the memory cell is conductive, then SEN_C is charged. If the memory cell is not conductive, then SEN_C is not charged.

The sense transistor (SEN tr) 905 is used to test the magnitude of the voltage on SEN_C. Specifically, a strobe transistor 903 is turned on by STRO to test the magnitude of the voltage on SEN. The latch 322 represents the sense node latch 322 (see FIG. 3). The value of the latch 322 is determined by the voltage level on the node L, where the node L may be pre-charged to the high VHLB_C level and then, depending on the voltage level on the SEN_C node, either charged or not through the transistor SEN tr 905 to the node VLOP during a strobe operation when the transistor STRO 903 is turned on. As noted, the voltage level on the SEN_C node may be pre-charged to VHLB_C through HLL transistor 909, after which it is connected to a selected bit line.

To hold charge on the SEN_C node, a sensing capacitor Cₛₑₙ 907 is connected to the SEN_C node. As illustrated by the broken line arrows, the upper plate of Cₛₑₙ 907 can be pre-charged by way of the pre-charge transistor HLL transistor 909, and then charged by a current from a selected memory cell along a corresponding bit line by an amount depending on how much current passes through the selected memory cell to set a voltage level on SEN_C. The level on SEN_C will then control the amount of current charged from the node L, and the state latched in DL 322, by way of the sensing transistor SEN tr 905.

FIG. 9 also depicts transistors that may be used to charge the bit line during programming. There are two charging paths for charging the bit line. A first path allows the bit line to be charged to VDDSA by a path through transistor 906, BLX transistor 908, BLC transistor 913. A second path allows the bit line to be charged to SRCGND by a path through transistor 902, BLX transistor 908, and BLC transistor 913. In some embodiments, the bit line is charged to VDSSA to inhibit programming or SRCGND to enable programming. Based on voltages at the control gate and drain of the BLC transistor 913, the BLC transistor can operate as a pass gate or as a bit line clamp. When the voltage at the control gate is sufficiently higher than the voltage on the drain, BLC transistor 913 operates as a pass gate. For example, a program-inhibit voltage such as 2.2 V (e.g., VDSSA) may be passed to the bit line when pre-charging and inhibiting an unselected NAND string. Or, a program-enable voltage such as 0V (e.g., SRCGND) may be passed to the bit line to allow programming in a selected NAND string.

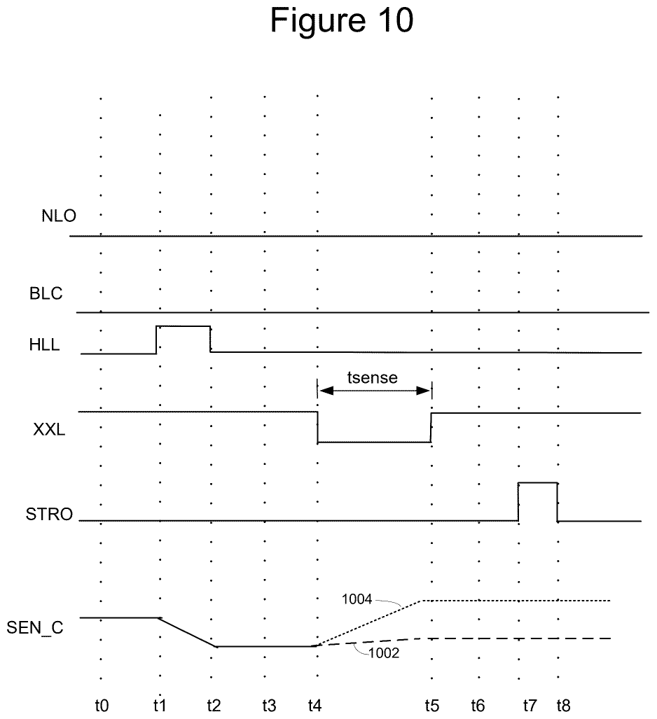

FIG. 10 depicts timing signals in sense amplifier 325 of FIG. 9 in connection with an embodiment of sensing a memory cell. The NLO signal may be low throughout the time periods depicted in FIG. 10. As discussed above, the NLO transistor 915 may clamp the voltage at the SCOM_C node. Likewise, the BLC signal may be low throughout the time periods depicted in FIG. 10.

Between t1 and t2, HLL is optionally raised high to pre-charge the sense node SEN_C. As a result, the voltage at SEN_C is charged to the pre-charge voltage. In an embodiment, SEN_C is set to 0V, but SEN_C may be established at a non-zero voltage. At time t2, HLL goes low, which turns off HLL transistor 709 to stop the pre-charging.

After time t3, a sensing voltage has been established on the SEN_C node. Also, the word line voltage (not depicted in FIG. 10) has been established at a target reference level. Also, the source line voltage (not depicted in FIG. 10) has been provided to the source line. Also, the bit line voltage (not depicted in FIG. 10) has been clamped by BLC transistor 913 to a target voltage. Note that this sense amplifier does not require that SEN_C be clocked up (see for contrast, the clock up to SEN_D at t3 in FIG. 8).

Referring to FIG. 10, at t4, the signal XXL goes high. Also note that BLC may be low at this time (note that the BLC transistor 913 is on when the BLC signal is low). Referring now to FIG. 9, XXL is provided to the gate of XXL transistor 911, thus turning on the PMOS XXL transistor 911. Also, the PMOS BLC transistor 913 is on at this time. This connects the sense node SEN_C to the bit line. The capacitor 907 is allowed to charge by the connected to the bit line and NAND string (including the selected memory cell being sensed). The managing circuit will wait for a sensing time (tsense). Referring to FIG. 9, the signal XXL remains low (e.g., active low) from t4 to t5. Also referring to FIG. 10, between t4 and t5, the sense node SEN_C charges. Two different charge rates are depicted. Plot 1002 is associated with a memory cell having a low conduction current, and plot 1004 is associated with a memory cell having a high conduction current. Stated another way, plot 1002 is associated with a memory cell having a threshold voltage above the reference level. Plot 1004 is associated with a memory cell having a threshold voltage below the reference level.

Next, the voltage on the capacitor 907 is tested at t7. The managing circuit will calculate the change in voltage across the capacitor 907 from the initial SEN_C voltage at t4 to the voltage after t5. Referring to FIG. 10, at t7, the strobe signal STRO goes high. Referring to FIG. 9, the sense transistor 905 will be either on or off in response to the voltage on the sense node SEN_C. With the strobe signal STRO high, transistor 903 is on, which provides a current path between the sense transistor 905 and the latch circuit 322. The latch circuit 322 will be set based on whether the sense transistor 905 conducts.

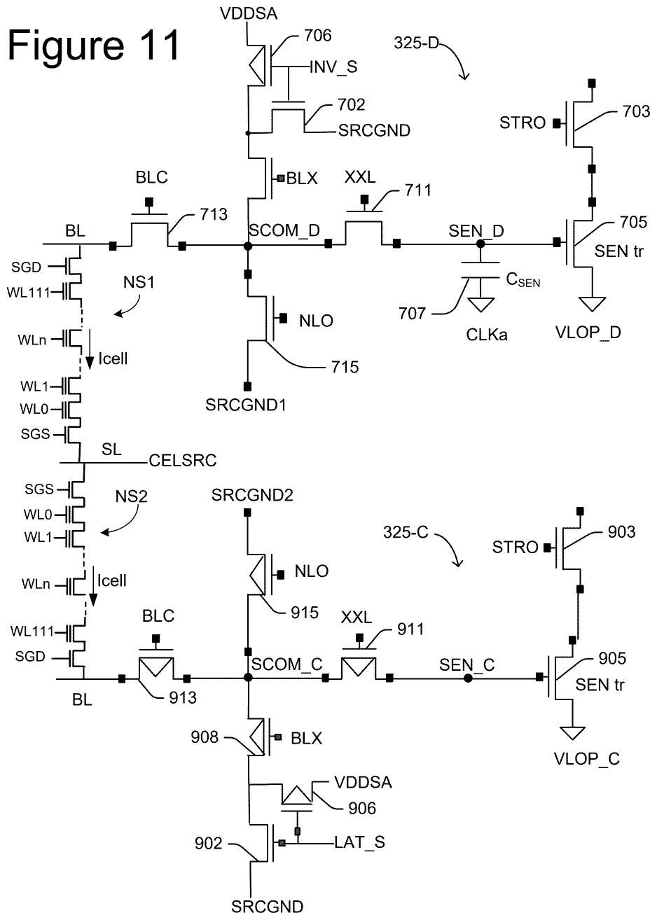

FIG. 11 is a schematic diagram of two sense amplifiers 325-C, 325-D in a configuration that allows recycling of current during read. The configuration is one embodiment of the current recycling technique depicted in FIG. 6A. SA 325-D is connected to NAND string NS1 to sense a selected memory cell on NS1. SA 325-C is connected to NAND string NS2 to sense a selected memory cell on NS2. The two NAND strings NS1, NS2 are connected to a common source line (SL), which is connected to a voltage source CELSRC. The cell current (Icell) for NS1 flows from bit line to source line. The cell current (Icell) for NS2 flows from source line to bit line.

NLO transistor 715 in SA 325-D is connected to a voltage source SRCGND1. As has been described above, the bit line connected to NS1 may be charged when NLO transistor 715 and BLC transistor 713 are on. NLO transistor 915 in SA 325-C is connected to a voltage source SRCGND2. As has been described above, the bit line connected to NS2 may be charged when NLO transistor 915 and BLC transistor 913 are on. SRCGND1 has a higher magnitude than SRCGND2. CELSRC may be about midway between SRCGND1 and SRCGND2. An example voltage for SRCGND1 is 2V. An example voltage for SRCGND2 is 0V. An example voltage for CELSRC is 1V. These are example voltages and all could be higher or lower with the constraint that SRCGND1>CELSRC>SRCGND2. Therefore, the current may flow from SRCGND1 through NS1, then to NS2 (by way of common source line) and then to SRCGND2, which is one example of recycling current during read.

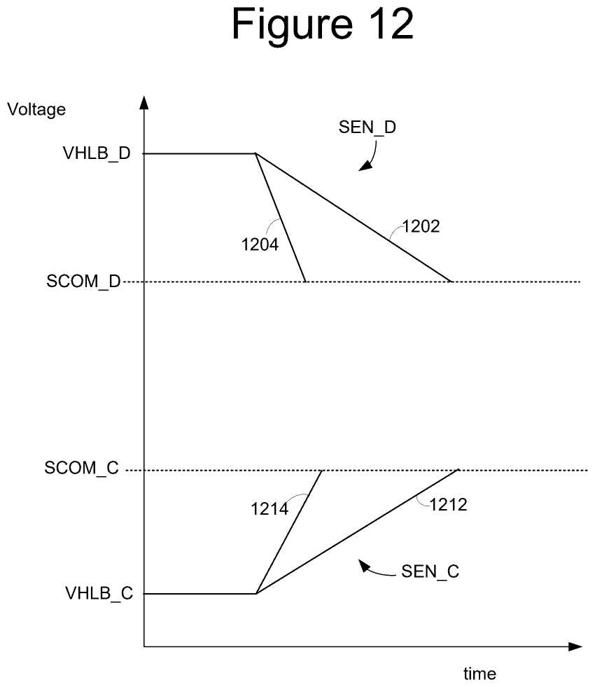

FIG. 12 shows voltages versus time at the SEN nodes and SCOM nodes of the sense amplifiers in FIG. 11. The voltage at SCOM_D is significantly higher than the voltage on SCOM_C. Prior to sensing, SEN_D is charged to VLHB_D and SEN_C is charged to VLHB_C. VLHB_C has a considerably lower magnitude than VLHB_D. FIG. 12 shows two example plots 1202, 1204 of the voltage on SEN_D being discharged by cell currents of two different magnitudes. The voltage on SEN_D can only fall as far as SCOM_D. However, note that in practice the voltage on SEN_D will not always fall all the way to SCOM_D due to the limited sensing time (Tsense). FIG. 12 shows two example plots 1212, 1214 of the voltage on SEN_C being charged by cell currents of two different magnitudes. The voltage on SEN_C can only rise as far as SCOM_C. However, note that in practice the voltage on SEN_C will not always rise all the way to SCOM_C due to the limited sensing time (Tsense). Significantly, there is no overlap between plots 1202, 1204 and 1212, 1214; therefore, one option is for the characteristic (e.g., Vt) of SEN tr 705 to be different from SEN tr 905. Another option is for VLOP_D to be different from VLOP_C.

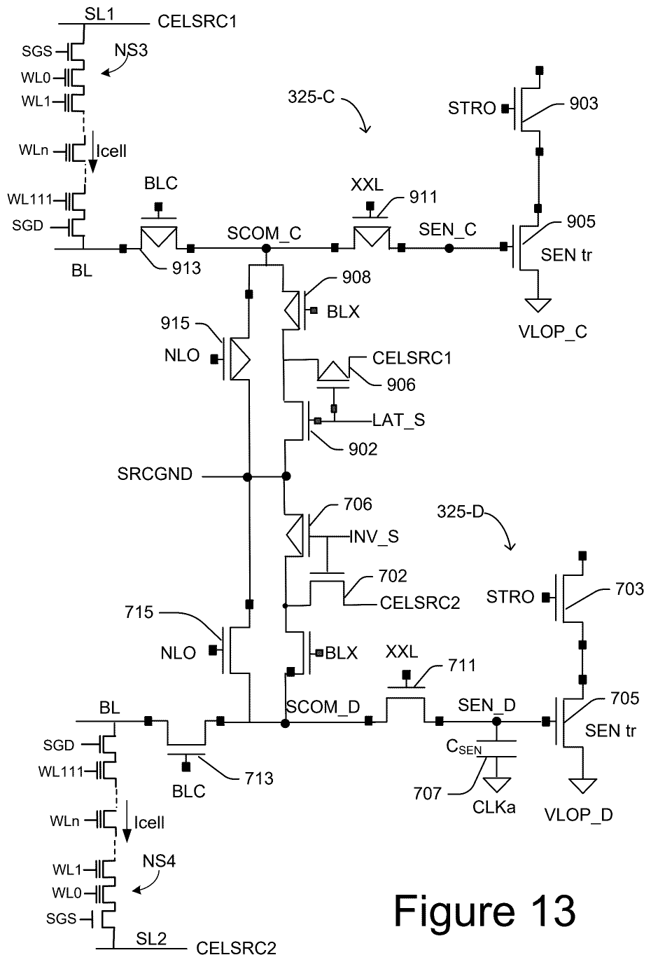

FIG. 13 is a schematic diagram of two sense amplifiers 325-C, 325-D in a configuration that allows recycling of current during read. The configuration is one embodiment of the current recycling technique depicted in FIG. 6B. SA 325-C is connected to NAND string NS3 to sense a selected memory cell on NS3. SA 325-D is connected to NAND string NS4 to sense a selected memory cell on NS4. The two NAND strings NS3, NS4 are connected to different source lines, driven by different voltages. NAND string NS3 is connected to SL1, which is connected to CELSRC1. NAND string NS4 is connected to SL2, which is connected to CELSRC2. The cell current (Icell) for NS4 flows from bit line to source line. The cell current (Icell) for NS3 flows from source line to bit line.

NLO transistor 715 in SA 325-D and NLO transistor 915 in SA 325-C are each connected to SRCGND. The bit line connected to NS4 may be charged when NLO transistor 715 and BLC transistor 713 are on. The bit line connected to NS3 may be charged when NLO transistor 915 and BLC transistor 913 are on. An example voltage for CELSRC1 is 2V. An example voltage for CELSRC2 is 0V. An example voltage for SRCGND is midway between CELSRC1 and CELSRC2, for example, 1V. These voltages are all examples and could be higher or lower with the constraint that CELSRC1 >SRCGND>CELSRC2. Therefore, the current may flow from CELSRC1 through NS3, then to NS4 (by way of common connection in SA 325-C and SA 325-D to SRGGND), and then to CELSRC2, which is one example of recycling current during read.

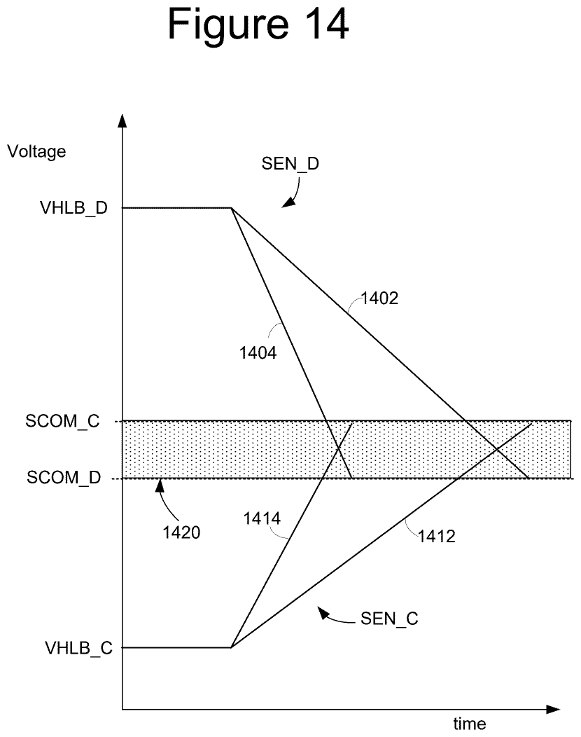

FIG. 14 shows voltages versus time at the SEN nodes and SCOM nodes of the sense amplifiers in FIG. 13. The voltage at SCOM_C may be slightly higher than the voltage on SCOM_D. Prior to sensing, SEN_D is charged to VLHB_D and SEN_C is charged to VLHB_C. VLHB_C has a considerably lower magnitude than VLHB_D. FIG. 14 shows two example plots 1402, 1404 of the voltage on SEN_D being discharged by cell currents of two different magnitudes. The voltage on SEN_D can only fall as far as SCOM_D. However, note that in practice the voltage on SEN_D will not always fall all the way to SCOM_D due to the limited sensing time (Tsense). FIG. 14 shows two example plots 1412, 1414 of the voltage on SEN_C being charged by cell currents of two different magnitudes. The voltage on SEN_C can only rise as far as SCOM_C. However, note that in practice the voltage on SEN_C will not always rise all the way to SCOM_C due to the limited sensing time (Tsense). Significantly, there is overlap 1420 between plots 1402, 1404 and 1412, 1414. Therefore, this allows characteristics (e.g., Vt) of SEN tr 705 to be the same as SEN tr 905.

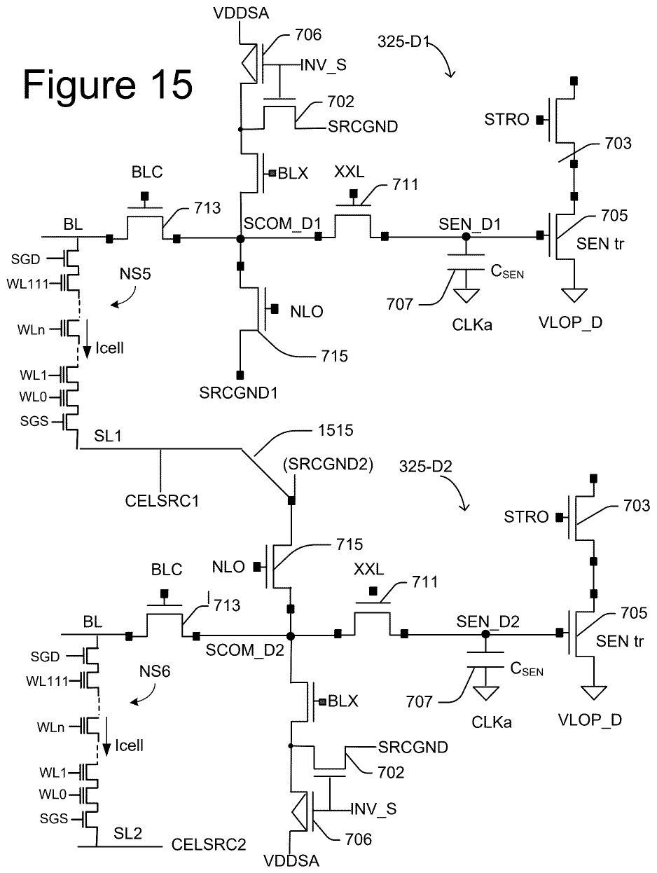

FIG. 15 is a schematic diagram of two sense amplifiers 325-D1, 325-D2 in a configuration that allows recycling of current during read. The configuration is one embodiment of the current recycling technique depicted in FIG. 6D. SA 325-D1 is connected to NAND string NS5 to sense a selected memory cell on NS5. SA 325-D2 is connected to NAND string NS6 to sense a selected memory cell on NS6. The two NAND strings NS5, NS6 are connected to different source lines, driven by different voltages. NAND string NS5 is connected to SL1, which is connected to CELSRC1. NAND string NS6 is connected to SL2, which is connected to CELSRC2. The cell current (Icell) for NS5 flows from bit line to source line. The cell current (Icell) for NS6 flows from bit line to source line.

For at least the read operation, there is a connection 1515 between SL1 and the NLO transistor 715 in SA 325-D2, which allows for recycling of current. NLO transistor 715 in SA 325-D1 is connected to SRCGND 1. NLO transistor 715 in SA 325-D2 is connected to SRCGND 2. However, NLO transistor 715 in SA 325-D2 is also connected to SL 1. The bit line connected to NS5 may be charged (using SRCGND1) when NLO transistor 715 and BLC transistor 713 in SA 325-D1 are on. The bit line connected to NS6 may be charged when NLO transistor 715 and BLC transistor 713 in SA 325-D2 are on. An example voltage for SRCGND 1 is 2V. An example voltage for CELSRC 2 is 0V. An example voltage for CELSRC 1 is midway between SRCGND and CELSRC2, for example, 1V. These voltages are all examples and could be higher or lower with the constraint that SRCGND1>CELSRC1>CELSRC2. Therefore, the current may flow from SRCGND1 through NS5, then to NS6 (by way of connection 1515 in SA 325-D2, and then to CELSRC 2, which is one example of recycling current during read. Note that SRCGND2 is depicted in FIG. 15 for consistency with FIG. 6D, but is not needed in view of CELSRC1.

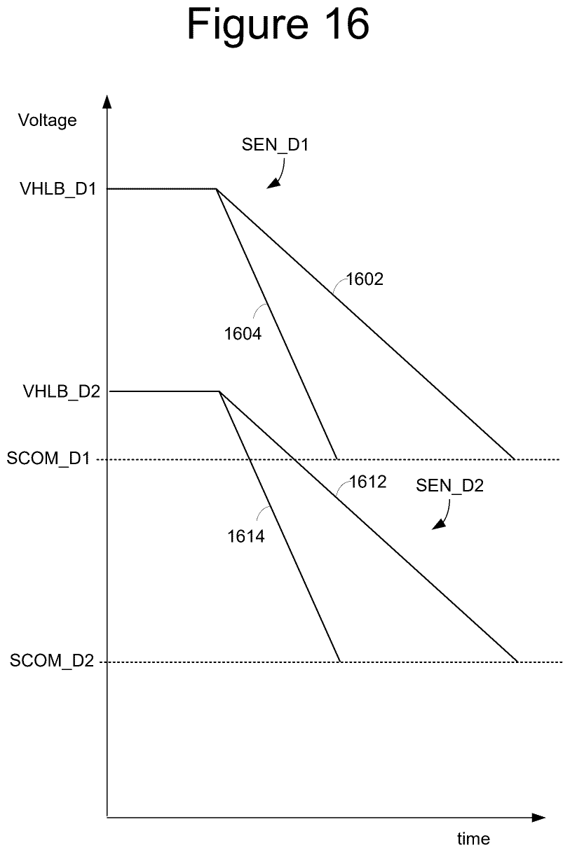

FIG. 16 shows voltages versus time at the SEN nodes and SCOM nodes of the sense amplifiers in FIG. 15. The voltage at SCOM_D1 may be somewhat higher than the voltage on SCOM_D2. Prior to sensing, SEN_D1 is charged to VLHB_D1 and SEN_D2 is charged to VLHB_D2. VLHB_D1 has a considerably higher magnitude than VLHB_D2. FIG. 16 shows two example plots 1602, 1604 of the voltage on SEN_D1 being discharged by cell currents of two different magnitudes. The voltage on SEN_D1 can only fall as far as SCOM_D1. However, note that in practice the voltage on SEN_D1 will not always fall all the way to SCOM_D1 due to the limited sensing time (Tsense). FIG. 16 shows two example plots 1612, 1614 of the voltage on SEN_D2 being discharged by cell currents of two different magnitudes. The voltage on SEN_D2 C can only fall as far as SCOM_D2. However, note that in practice the voltage on SEN_D2 will not always rise all the way to SCOM_D2 due to the limited sensing time (Tsense). Recall that for the SA 325-D there may be a CLKa applied to the sense transistor 707. In an embodiment, the magnitude of CLKa is different in SA 325-D1 than SA 325-D2 in order to compensate for the different levels of SCOM_D 1 and SCOM_D 2. For example, CLKa may be larger for SA 325-D1 than SA 325-D2. This compensation allows the sense transiters 705 in the two SA 325-D1, 325-D2 to have the same characteristics (e.g., the same Vt).

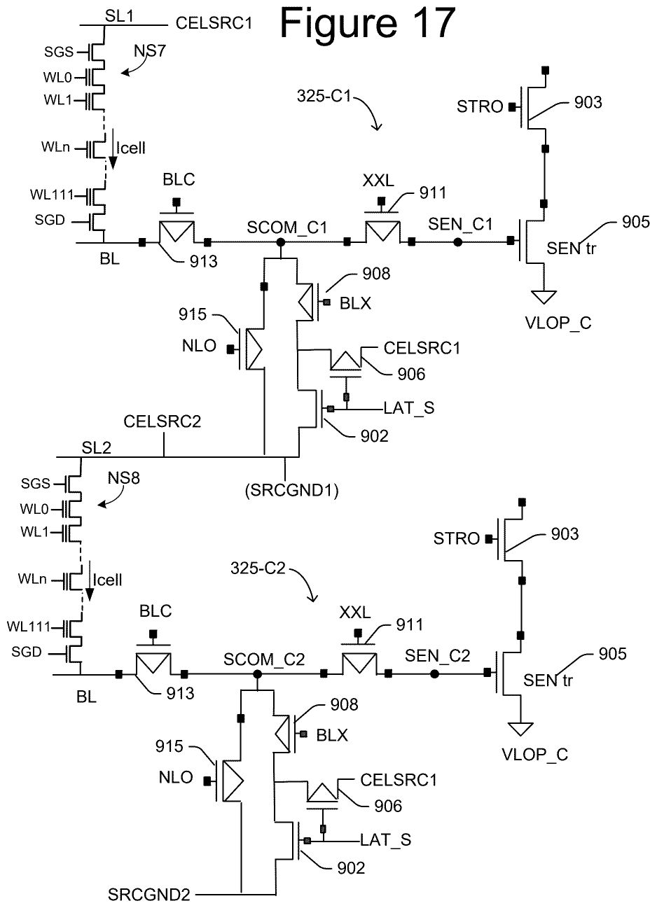

FIG. 17 is a schematic diagram of two sense amplifiers 325-C1, 325-C2 in a configuration that allows recycling of current during read. The configuration is one embodiment of the current recycling technique depicted in FIG. 6C. SA 325-C1 is connected to NAND string NS7 to sense a selected memory cell on NS 7. SA 325-C2 is connected to NAND string NS8 to sense a selected memory cell on NS8. The two NAND strings NS7, NS8 are connected to different source lines, driven by different voltages. NAND string NS7 is connected to SL1, which is connected to CELSRC1. NAND string NS8 is connected to SL2, which is connected to CELSRC2. The cell current (Icell) for NS7 flows from source line to bit line. The cell current (Icell) for NS8 flows from source line to bit line.

The NLO transistor 915 in SA 325-C1 is connected to SL 1. There is a current pathway from CELSRC1 through NS7, through BLC transistor 913 and NLO transistor 915 in SA 325-C1 to SL 2 (driven by CELSCR 2). The current pathway continues from SL 2 through NS 8, through BLC transistor 913 and NLO transistor 915 in SA 325-C2 to SRCGND 2, which is one example of recycling current during read. The bit line connected to NS7 may be charged when NLO transistor 915 and BLC transistor 913 in SA 325-C1 are on. The bit line connected to NS 8 may be charged when NLO transistor 915 and BLC transistor 913 in SA 325-C2 are on. An example voltage for CELSRC 1 is 2V. An example voltage for SRCGND 2 is 0V. An example voltage for CELSRC2 is midway between CELSRC1 and SRCGND2, for example, 1V. These voltages are all examples and could be higher or lower with the constraint that CELSRC1>CELSRC2>SRCGND2. Therefore, the current may flow from CELSRC1 through NS7, then to NS8, and then to SRCGND2, which is one example of recycling current during read. Note that SRCGND1 is depicted in FIG. 17 for consistency with FIG. 6C, but is not needed in view of CELSRC2.

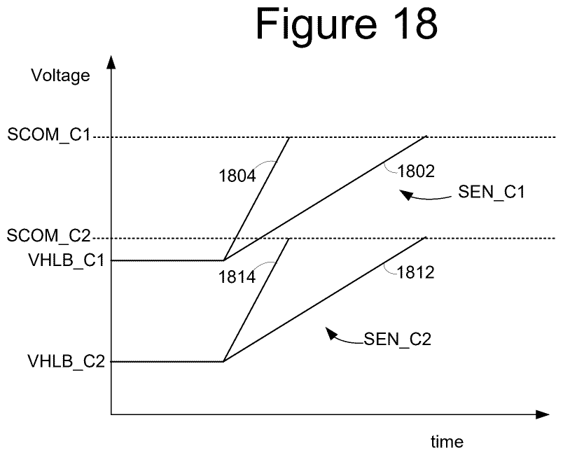

FIG. 18 shows voltages versus time at the SEN nodes and SCOM nodes of the sense amplifiers in FIG. 17. The voltage at SCOM_C1 may be slightly higher than the voltage on SCOM_C2. Prior to sensing, SEN_C1 is charged to VLHB_C1 and SEN_C2 is charged to VLHB_C2. VLHB_C2 has a lower magnitude than VLHB_C1. FIG. 18 shows two example plots 1802, 1804 of the voltage on SEN_C1 being charged by cell currents of two different magnitudes. The voltage on SEN_C1 can only rise as far as SCOM_C1. However, note that in practice the voltage on SEN_C1 will not always rise all the way to SCOM_C1 due to the limited sensing time (Tsense). FIG. 18 shows two example plots 1812, 1814 of the voltage on SEN_C2 being charged by cell currents of two different magnitudes. The voltage on SEN_C2 can only rise as far as SCOM_C2. However, note that in practice the voltage on SEN_C2 will not always rise all the way to SCOM_C2 due to the limited sensing time (Tsense). Due to the different voltages at SCOM_C1 and SCOM_C2 one option is to clock down the voltage on SEN_C1 (similar to how CLKa is used in SA 325-D), which allows the sense transistors 905 in SA 325-C1 and 325-C2 to have the same characteristics (e.g., the same Vt). However, another option is to have different characteristics for the sense transistors 905 in SA 325-C1 and 325-C2.

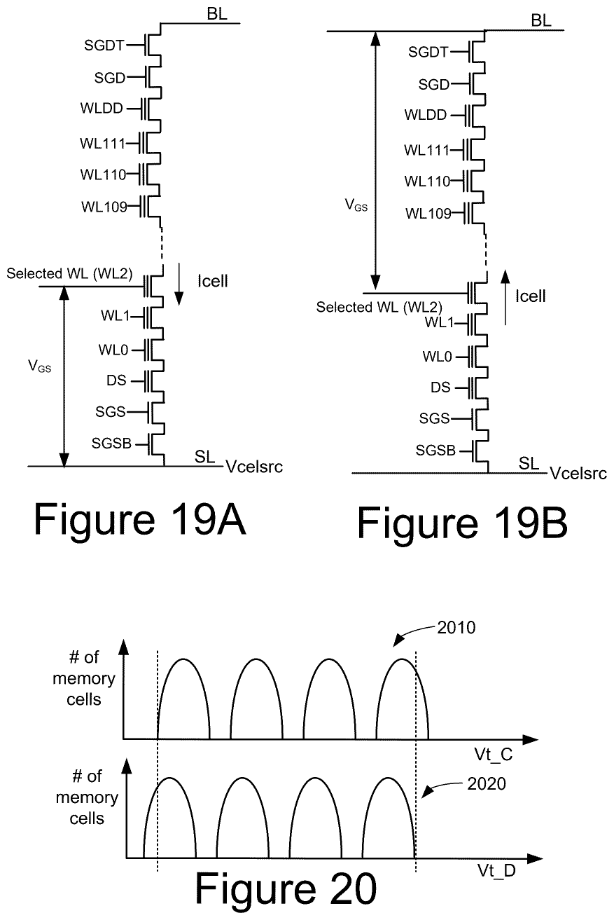

In some embodiments, Icell flows in a different direction in the first set of NAND strings then in the second set of NAND strings. For example, FIGS. 6A and 6B shows Icell flowing bit line to source line in the first NAND strings 501-A, but flowing source line to bit line in the first NAND strings 501-B. The direction of Icell has an impact on the Vgs of the selected memory cell. FIGS. 19A and 19B each show an example NAND string in which memory cells connected to the same word line are selected for read. In FIG. 19A the cell current Icell flows from bit line to source line; therefore, Vgs is the difference in voltage between the selected word line and the source line. In FIG. 19B the cell current Icell flows from source line to bit line; therefore, Vgs is the difference in voltage between the selected word line and the bit line.

In one embodiment, the same current recycle scheme is used for both verify and read to mitigate the effects of the different Vgs. FIG. 20 shows an example set of Vt distributions 2010 for sensing with the current flowing source line to bit line and an example set of Vt distributions 2020 for sensing with the current flowing bit line to source line. The same verify reference voltage is used for all of the cells and the same read reference voltage is used for all of the cells. However, due to the different Vgs experienced by the cells in the two sets of NAND strings, there may be an actual difference in Vt. For example, distributions 2010 may have their Vts (Vt_C) shifted relative to distributions 2020 (Vt_D). However, as long as the sensing scheme is consistent between verify and read the shift happens during both verify and read, which in effect cancels out the effect of the different Vgs.

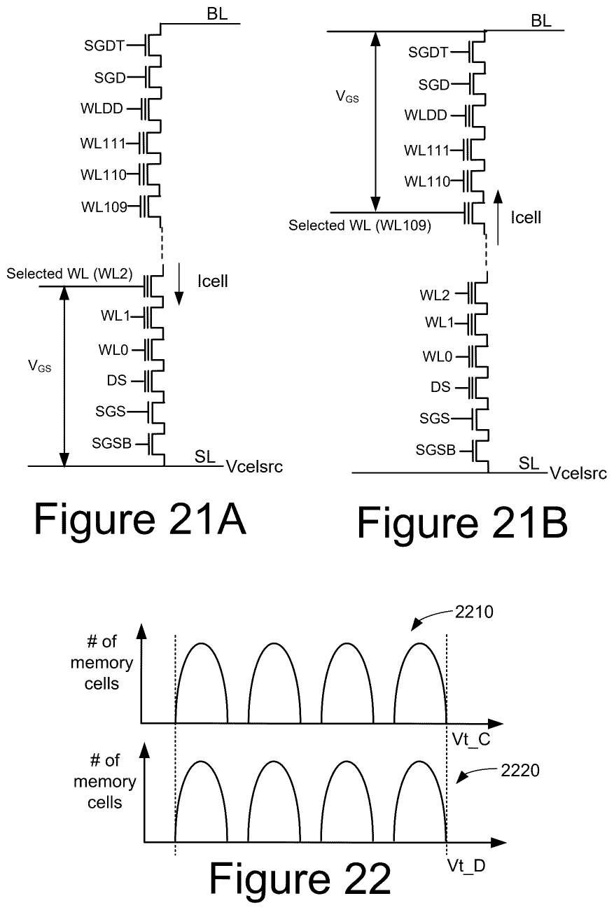

In one embodiment, the memory system selects a different word line for the NAND strings having Icell flowing from bit line to source line than NAND strings having Icell flowing from source line to bit line. FIGS. 21A and 21B shows schematics of example NAND strings illustrating selecting a different word line for a NAND string having Icell flowing from bit line to source line than a NAND string having Icell flowing from source line to bit line. In FIG. 21A, the memory system selects WL2. However, in FIG. 21B, the memory system selects WL109 in order to achieve the same (or very close to the same) Vgs for the selected memory cells. In this example, the memory system selects WL109 in FIG. 21B based on its distance to the bit line being substantially the same as the distance of WL2 to the source line in FIG. 21A. In some cases a factor other than the distance may be used to achieve substantially the same Vgs for the NAND strings having Icell flowing from bit line to source line as the NAND strings having Icell flowing from source line to bit line. In some embodiments, an architecture such as in FIG. 4F3 or 4F4 is used in order to select a different word line in one half of the block than the other half of the block.

FIG. 22 shows an example set of Vt distributions 2210 for sensing with the current flowing source line to bit line and an example set of Vt distributions 2220 for sensing with the current flowing bit line to source line for the technique used in FIGS. 21A and 21B. The same verify reference voltage is used for all of the cells and the same read reference voltage is used for all of the cells. However, due to the different word lines selected all selected memory cells have substantially the same Vgs. Therefore, there is not a shift in the distributions 2220 relative to distributions 2210.

In view of the foregoing, a first embodiment includes an apparatus comprising a memory structure having a plurality of NAND strings, a plurality of word lines connected to the plurality of NAND strings having memory cells, and a plurality of bit lines associated with the plurality of NAND strings. The apparatus comprises one or more control circuits in communication with the memory structure. The one or more control circuits include a first plurality of sense amplifiers configured to sense memory cells on a first set of the plurality of NAND strings. The first set of NAND strings are associated with a first set of bit lines of the plurality of bit lines. The one or more control circuits include a second plurality of sense amplifiers configured to sense memory cells on a second set of the plurality of NAND strings. The second set of NAND strings are associated with a second set of bit lines of the plurality of bit lines. The one or more control circuits are configured to apply a reference voltage to a first set of selected memory cells on the first set of NAND strings and a second set of selected memory cells on the second set of NAND strings while applying a pass voltage to unselected memory cells on the first set of NAND strings and the second set of NAND strings during a sense operation thereby resulting in first currents in the first set of NAND strings and second currents in the second set of NAND strings. The one or more control circuits are configured to operate the first plurality of sense amplifiers and the second plurality of sense amplifiers to recycle the first currents for use as a current source for the second currents during the sense operation.

In a further embodiment of the apparatus the first set of NAND strings and the second set of NAND strings are connected to a common source line to which the first currents sink and from which the second currents are sourced in order to recycle the first currents for use as the current source for the second currents during the sense operation.

In a further embodiment of the apparatus the first plurality of sense amplifiers are configured to sense memory cell currents that flow from the first set of bit lines to the common source line. And the second plurality of sense amplifiers are configured to sense memory cell currents that flow from the common source line to the second set of bit lines.

In a further embodiment of the apparatus, the first set of NAND strings are connected to a first source line, the second set of NAND strings are connected to a second source line, and the first set of sense amplifiers and the second set of sense amplifiers are connected to a common node to which the first currents flow and from which the second currents are sourced in order to recycle the first currents for use as the current source for the second currents during the sense operation.

In a further embodiment of the apparatus, the first plurality of sense amplifiers are configured to sense memory cell currents that flow from the first source line to the first set of bit lines and the second plurality of sense amplifiers are configured to sense memory cells currents that flow from the second set of bit lines to the second source line.

In a further embodiment of the apparatus, the first set of NAND strings are connected to a first source line, the second set of NAND strings are connected to a second source line, and the first set of sense amplifiers are connected to the second source line. The first currents flow from the first set of NAND strings to first set of sense amplifiers to the second source line and then to second set of NAND strings to in order to recycle the first currents for use as the current source for the second currents during the sense operation.

In a further embodiment of the apparatus, the first plurality of sense amplifiers are configured to sense memory cells currents that flow from the first source line to the first set of bit lines. And the second plurality of sense amplifiers are configured to sense memory cells currents that flow from the second source line to the second set of bit lines.

In a further embodiment of the apparatus, the first set of NAND strings are connected to a first source line, the second set of NAND strings are connected to a second source line, and the second set of sense amplifiers are connected to the first source line. The first currents flow from the first set of NAND strings to the first source line to the second set of sense amplifiers and then to second set of NAND strings to in order to recycle the first currents for use as the current source for the second currents during the sense operation.

In a further embodiment of the apparatus, the first plurality of sense amplifiers are configured to sense memory cells currents that flow from the first set of bit lines to the first source line and the second plurality of sense amplifiers are configured to sense memory cells currents that flow from the second set of bit lines to the second source line.

In a further embodiment of the apparatus, the first plurality of sense amplifiers are configured to sense memory cells currents that flow from the first set of bit lines to a source line, the second plurality of sense amplifiers are configured to sense memory cells currents that flow from a source line to the second set of bit lines. And the one or more control circuits are configured to apply a verify reference voltage to a selected word line connected to the first set of selected memory cells and the second set of selected memory cells during a verify operation and apply a read reference voltage to the selected word line connected to the first set of selected memory cells and the second set of selected memory cells during a read operation.

In a further embodiment of the apparatus, the first plurality of sense amplifiers are configured to sense memory cells currents that flow from the first set of bit lines to a source line connected to the first set of NAND strings, the second plurality of sense amplifiers are configured to sense memory cells currents that flow from a source line connected to the second set of NAND strings to the second set of bit lines. And the one or more control circuits are configured to apply the reference voltage to a first selected word line connected to the first set of selected memory cells and a second selected word line connected to the second set of selected memory cells during the sense operation. A first distance from the first selected word line to the source line connected to the first set of NAND strings is substantially equal to a second distance from the second selected word line to the second set of bit lines.

An embodiment includes a method for sensing NAND memory cells. The method comprises applying a reference voltage to a first set of selected NAND memory cells on a first set of NAND strings and a second set of selected NAND memory cells on a second set of NAND strings while applying a pass voltage to unselected memory cells on the first set of NAND strings and the second set of NAND strings during a sense operation of the first set of selected memory cells and the second set of selected memory cells to thereby result in first NAND string currents of the first set of NAND strings and second NAND string currents of the second set of NAND string. The method comprises providing a current pathway between the first set of NAND strings and the second set of NAND strings such that the first NAND string currents serve as a source of current for the second NAND string currents during the sense operation.

An embodiment includes a non-volatile storage system, comprising a memory structure having a plurality of NAND strings, a plurality of word lines connected to the plurality of NAND strings, and a plurality of bit lines associated with the plurality of NAND strings. The non-volatile storage system includes one or more control circuits in communication with the memory structure. The one or more control circuits include a first plurality of sense amplifiers configured to sense memory cells on a first set of the plurality of NAND strings. The first set of NAND strings are associated with a first set of bit lines of the plurality of bit lines. The one or more control circuits include a second plurality of sense amplifiers configured to sense memory cells on a second set of the plurality of NAND strings. The second set of NAND strings are associated with a second set of bit lines of the plurality of bit lines. The one or more control circuits are configured to control the first plurality of sense amplifiers to charge the first set of bit lines with first bit line charging currents during a sense operation of selected memory cells on the first set of NAND strings. The one or more control circuits are configured to control the second plurality of sense amplifier to charge the second set of bit lines with second bit line charging currents during the sense operation of selected memory cells on the second set of NAND strings, including recycle the first bit line charging currents for use as a current source for the second bit line charging currents during the sense operation.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
a memory structure having a plurality of NAND strings, a plurality of word lines connected to the plurality of NAND strings having memory cells, and a plurality of bit lines associated with the plurality of NAND strings; and
one or more control circuits in communication with the memory structure, the one or more control circuits including:
a first plurality of sense amplifiers configured to sense memory cells on a first set of the plurality of NAND strings, the first set of NAND strings associated with a first set of bit lines of the plurality of bit lines; and
a second plurality of sense amplifiers configured to sense memory cells on a second set of the plurality of NAND strings, the second set of NAND strings associated with a second set of bit lines of the plurality of bit lines, wherein the one or more control circuits are configured to:
apply a reference voltage to a first set of selected memory cells on the first set of NAND strings and a second set of selected memory cells on the second set of NAND strings while applying a pass voltage to unselected memory cells on the first set of NAND strings and the second set of NAND strings during a sense operation thereby resulting in first currents in the first set of NAND strings and second currents in the second set of NAND strings; and
operate the first plurality of sense amplifiers and the second plurality of sense amplifiers to recycle the first currents for use as a current source for the second currents during the sense operation.

2. The apparatus of claim 1, wherein the first set of NAND strings and the second set of NAND strings are connected to a common source line to which the first currents sink and from which the second currents are sourced in order to recycle the first currents for use as the current source for the second currents during the sense operation.

3. The apparatus of claim 2, wherein:
the first plurality of sense amplifiers are configured to sense memory cell currents that flow from the first set of bit lines to the common source line; and
the second plurality of sense amplifiers are configured to sense memory cell currents that flow from the common source line to the second set of bit lines.

4. The apparatus of claim 1, wherein:
the first set of NAND strings are connected to a first source line;
the second set of NAND strings are connected to a second source line; and
the first set of sense amplifiers and the second set of sense amplifiers are connected to a common node to which the first currents flow and from which the second currents are sourced in order to recycle the first currents for use as the current source for the second currents during the sense operation.

5. The apparatus of claim 4, wherein:
the first plurality of sense amplifiers are configured to sense memory cell currents that flow from the first source line to the first set of bit lines; and
the second plurality of sense amplifiers are configured to sense memory cells currents that flow from the second set of bit lines to the second source line.

6. The apparatus of claim 1, wherein:
the first set of NAND strings are connected to a first source line;
the second set of NAND strings are connected to a second source line; and
the first set of sense amplifiers are connected to the second source line, wherein the first currents flow from the first set of NAND strings to first set of sense amplifiers to the second source line and then to second set of NAND strings to in order to recycle the first currents for use as the current source for the second currents during the sense operation.

7. The apparatus of claim 6, wherein:
the first plurality of sense amplifiers are configured to sense memory cells currents that flow from the first source line to the first set of bit lines; and
the second plurality of sense amplifiers are configured to sense memory cells currents that flow from the second source line to the second set of bit lines.

8. The apparatus of claim 1, wherein:
the first set of NAND strings are connected to a first source line;
the second set of NAND strings are connected to a second source line; and
the second set of sense amplifiers are connected to the first source line, wherein the first currents flow from the first set of NAND strings to the first source line to the second set of sense amplifiers and then to second set of NAND strings to in order to recycle the first currents for use as the current source for the second currents during the sense operation.

9. The apparatus of claim 8, wherein:
the first plurality of sense amplifiers are configured to sense memory cells currents that flow from the first set of bit lines to the first source line; and
the second plurality of sense amplifiers are configured to sense memory cells currents that flow from the second set of bit lines to the second source line.

10. The apparatus of claim 1, wherein:
the first plurality of sense amplifiers are configured to sense memory cells currents that flow from the first set of bit lines to a source line;
the second plurality of sense amplifiers are configured to sense memory cells currents that flow from a source line to the second set of bit lines; and
the one or more control circuits are configured to:
apply a verify reference voltage to a selected word line connected to the first set of selected memory cells and the second set of selected memory cells during a verify operation; and
apply a read reference voltage to the selected word line connected to the first set of selected memory cells and the second set of selected memory cells during a read operation.

11. The apparatus of claim 1, wherein:
the first plurality of sense amplifiers are configured to sense memory cells currents that flow from the first set of bit lines to a source line connected to the first set of NAND strings;
the second plurality of sense amplifiers are configured to sense memory cells currents that flow from a source line connected to the second set of NAND strings to the second set of bit lines; and
the one or more control circuits are configured to:
apply the reference voltage to a first selected word line connected to the first set of selected memory cells and a second selected word line connected to the second set of selected memory cells during the sense operation, wherein a first distance from the first selected word line to the source line connected to the first set of NAND strings is substantially equal to a second distance from the second selected word line to the second set of bit lines.

12. A method for sensing NAND memory cells, the method comprising:
applying a reference voltage to a first set of selected NAND memory cells on a first set of NAND strings and a second set of selected NAND memory cells on a second set of NAND strings while applying a pass voltage to unselected memory cells on the first set of NAND strings and the second set of NAND strings during a sense operation of the first set of selected memory cells and the second set of selected memory cells to thereby result in first NAND string currents of the first set of NAND strings and second NAND string currents of the second set of NAND string; and
providing a current pathway between the first set of NAND strings and the second set of NAND strings such that the first NAND string currents serve as a source of current for the second NAND string currents during the sense operation.

13. The method of claim 12, wherein providing the current pathway between the first set of NAND strings and the second set of NAND strings such that the first NAND string currents serve as a source of current for the second NAND string currents during the sense operation comprises:
controlling a first set of sense amplifiers associated with the first set of NAND strings and a second set of sense amplifiers associated with the second set of NAND strings to route the first NAND string currents through a common source line connected to the first set of NAND strings and the set of NAND strings such that the first NAND string currents serve as a source of current for the second NAND string currents during the sense operation.

14. The method of claim 12, wherein providing the current pathway between the first set of NAND strings and the second set of NAND strings such that the first NAND string currents serve as a source of current for the second NAND string currents during the sense operation comprises:
controlling a first set of sense amplifiers associated with the first set of NAND strings and a second set of sense amplifiers associated with the second set of NAND strings to route the first NAND string currents through the first set of sense amplifiers to the second set of sense amplifiers such that the first NAND string currents serve as a source of current for the second NAND string currents during the sense operation.

15. The method of claim 12, wherein providing the current pathway between the first set of NAND strings and the second set of NAND strings such that the first NAND string currents serve as a source of current for the second NAND string currents during the sense operation comprises:
controlling a first set of sense amplifiers associated with the first set of NAND strings and a second set of sense amplifiers associated with the second set of NAND strings to route the first NAND string currents through the first set of sense amplifiers to a source line connected to the second set of NAND strings such that the first NAND string currents serve as a source of current for the second NAND string currents during the sense operation.

16. The method of claim 12, wherein providing the current pathway between the first set of NAND strings and the second set of NAND strings such that the first NAND string currents serve as a source of current for the second NAND string currents during the sense operation comprises:
controlling a first set of sense amplifiers associated with the first set of NAND strings and a second set of sense amplifiers associated with the second set of NAND strings to route the first NAND string currents to a source line connected to the first set of NAND strings to the second set of sense amplifiers such that the first NAND string currents serve as a source of current for the second NAND string currents during the sense operation.

17. A non-volatile storage system, comprising:
a memory structure having a plurality of NAND strings, a plurality of word lines connected to the plurality of NAND strings, and a plurality of bit lines associated with the plurality of NAND strings; and
one or more control circuits in communication with the memory structure, the one or more control circuits including:
a first plurality of sense amplifiers configured to sense memory cells on a first set of the plurality of NAND strings, the first set of NAND strings associated with a first set of bit lines of the plurality of bit lines; and
a second plurality of sense amplifiers configured to sense memory cells on a second set of the plurality of NAND strings, the second set of NAND strings associated with a second set of bit lines of the plurality of bit lines, wherein the one or more control circuits are configured to:
control the first plurality of sense amplifiers to charge the first set of bit lines with first bit line charging currents during a sense operation of selected memory cells on the first set of NAND strings; and
control the second plurality of sense amplifiers to charge the second set of bit lines with second bit line charging currents during the sense operation of selected memory cells on the second set of NAND strings, including recycle the first bit line charging currents for use as a current source for the second bit line charging currents during the sense operation.

18. The non-volatile storage system of claim 17, wherein:
the first set of NAND strings are connected to a first source line;
the second set of NAND strings are connected to a second source line; and
the first plurality of sense amplifiers each have a node connected to the second source line.

19. The non-volatile storage system of claim 17, wherein:
the first plurality of sense amplifiers each have a transistor connected to a common node, the common node sinks the first bit line charging currents; and
the second plurality of sense amplifiers each have a transistor connected to the common node, the common node sources the second bit line charging currents.

20. The non-volatile storage system of claim 17, wherein:
the first plurality of sense amplifiers are configured to sense memory cell currents that flow from a source line connected to the first set of NAND strings to the first set of bit lines; and
the second plurality of sense amplifiers are configured to sense memory cell current that flows from the second set of bit line to a source line connected to the second set of NAND strings.
